(19) United States
(12) Patent Application Publication
(10) Pub. No.: US 2026/0190595 A1
(43) Pub. Date: Jul. 2, 2026

(54) DISPLAY DEVICE, ELECTRONIC DEVICE INCLUDING THE SAME, AND METHOD FOR FABRICATING THE SAME

(71) Applicants: Samsung Display Co., LTD., Yongin-si (KR); POSTECH Research and Business Development Foundation, Pohang-si (KR)

(72) Inventors: Hyung Jun KIM, Yongin-si (KR); Yong-Young NOH, Pohang-si (KR); Sun Hee LEE, Yongin-si (KR); Youjin REO, Pohang-si (KR); Wantae Park, Pohang-si (KR)

(21) Appl. No.: 19/173,656

(22) Filed: Apr. 8, 2025

(30) Foreign Application Priority Data
Jan. 2, 2025 (KR) 10-2025-0000114

(51) Int. Cl. H10K 10/46; H10K 59/12; H10K 59/125

(52) U.S. Cl. CPC H10K 10/484; H10K 59/1201; H10K 59/125

(57) ABSTRACT

A display device, an electronic device including the same, and a method of manufacturing the same are provided. A thin-film transistor includes: a substrate; a semiconductor layer on the substrate; a gate electrode that overlaps with a channel region of the semiconductor layer in a thickness direction of the substrate; a gate insulator between the semiconductor layer and the gate electrode to insulate (e.g., electrically insulate) the semiconductor layer from the gate electrode; and a source electrode and a drain electrode on a surface of the semiconductor layer, wherein the semiconductor layer may include a perovskite compound represented by the chemical formula: AA′₍ₙ₋₁₎SnₙX₍₃ₙ₊₁₎.

### CROSS-REFERENCE TO RELATED APPLICATION

The present application claims priority to and the benefit of Korean Patent Application No. 10-2025-0000114, filed on Jan. 2, 2025, in the Korean Intellectual Property Office, the entire content of which is hereby incorporated by reference.

### BACKGROUND

### 1. Field

Embodiments of the present disclosure relate to a display device, an electronic device including the same, and a method for fabricating the same.

### 2. Description of the Related Art

As the information-oriented society evolves, various demands for display devices are ever increasing. Display devices may be flat panel display devices such as, for example, a liquid-crystal display device, a field emission display device, and a light-emitting display device. Light-emitting display devices may include an organic light-emitting display device including an organic light-emitting element, an inorganic light-emitting display device including an inorganic light-emitting element such as an inorganic semiconductor, and a micro-light-emitting display device including an ultra-small light-emitting element.

Halide perovskite may be used as a semiconductor layer for a p-type transistor because it has low effective hole mass and thus is expected to have high hole/electron mobility. For example, lead-based halide perovskite and tin-based halide perovskite may be used as a semiconductor layer for a p-type transistor.

Lead-based halide perovskite has a problem in that it is harmful to the human body and the environment. Tin-based halide perovskite has an advantage over lead-based halide perovskite in that it is relatively harmless to the human body and the environment. However, tin-based halide perovskite may be oxidized by oxygen in the air, which may reduce electrical characteristics of the tin-based halide perovskite.

### SUMMARY

Aspects of embodiments of the present disclosure provide a display device that can prevent or reduce deterioration of electrical characteristics due to oxidation of a tin-based halide perovskite used as a semiconductor layer for a p-type thin-film transistor by oxygen in the air, an electronic device including the same, and a method for fabricating the same. These and other aspects of embodiments of the present disclosure will become readily apparent to those of ordinary skill in the art upon review of the Detailed Description and Claims to follow.

According to an aspect of embodiments of the present disclosure, there may be provided a thin-film transistor including: a substrate; a semiconductor layer on the substrate; a gate electrode that overlaps with a channel region of the semiconductor layer in a thickness direction of the substrate; a gate insulator may be between the semiconductor layer and the gate electrode to insulate (e.g., electrically insulate) the semiconductor layer from the gate electrode; and a source electrode and a drain electrode may be on a surface of the semiconductor layer, wherein the semiconductor layer may include a perovskite compound represented by the following chemical formula:

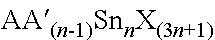

wherein A is R₁(NH₃⁺)₂ or

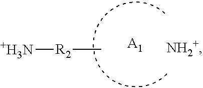

R₁ includes at least one selected from: a substituted or unsubstituted C₁₋₂₀ linear or branched alkyl group; a substituted or unsubstituted 5-membered unsaturated or aromatic ring; a substituted or unsubstituted 6-membered unsaturated or aromatic ring; a substituted or unsubstituted 5-membered unsaturated or aromatic heterocyclic group; and a substituted or unsubstituted 6-membered unsaturated or aromatic heterocyclic group, R₂ is a substituted or unsubstituted C₁₋₁₀ alkyl group, A₁ includes at least one selected from: a substituted or unsubstituted 5-membered unsaturated or aromatic heterocyclic group; and a substituted or unsubstituted 6-membered unsaturated or aromatic heterocyclic group, the heterocyclic group includes at least one selected from the group consisting of N, O and S, A′ includes at least one selected from Rb, Cs, K, Na, Mg, Ca, Sr, Ba and an organic cation, and X includes halogen, wherein n denotes an integer equal to or greater than one.

The R₁ may include a C₁₋₂₀ alkyl group, and wherein the A₁ may include a substituted or unsubstituted 6-membered unsaturated or aromatic heterocyclic group.

The R₁ may include an alkyl group represented by C₂ₘ, wherein m may be an integer from 1 to 10.

In embodiments, n may be 1.

The semiconductor layer may include grains, and a size of the grains may range from 10 μm to 50 μm.

A thickness of the semiconductor layer may range from 1 nm to 100 nm.

In the perovskite compound, a content of A may range from 50 mol % to 300 mol % based on 100 mol % of tin (Sn).

An electron mobility (e.g., of the semiconductor layer) may be equal to or less than 10 cm²/Vs.

A current on-off ratio (e.g., of the thin-film transistor) may range from 10 to 10⁷.

According to an aspect of embodiments of the present disclosure, there may be provided a display device including: a light-emitting element and a thin-film transistor, wherein the thin-film transistor may include: a substrate; a semiconductor layer on the substrate; a gate electrode that overlaps with a channel region of the semiconductor layer in a thickness direction of the substrate; a gate insulator between the semiconductor layer and the gate electrode to insulate (e.g., electrically insulate) the semiconductor layer from the gate electrode; and a source electrode and a drain electrode on a surface of the semiconductor layer, wherein the semiconductor layer may include a perovskite compound represented by the following chemical formula:

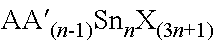

wherein A is R₁(NH₃⁺)₂ or

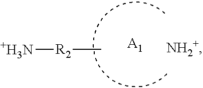

R₁ includes at least one selected from: a substituted or unsubstituted C₁₋₂₀ linear or branched alkyl group; a substituted or unsubstituted 5-membered unsaturated or aromatic ring; a substituted or unsubstituted 6-membered unsaturated or aromatic ring; a substituted or unsubstituted 5-membered unsaturated or aromatic heterocyclic group; and a substituted or unsubstituted 6-membered unsaturated or aromatic heterocyclic group, R₂ is a substituted or unsubstituted C₁₋₁₀ alkyl group, A₁ includes at least one selected from: a substituted or unsubstituted 5-membered unsaturated or aromatic heterocyclic group; and a substituted or unsubstituted 6-membered unsaturated or aromatic heterocyclic group, the heterocyclic group includes at least one selected from the group consisting of N, O and S, A′ includes at least one selected from Rb, Cs, K, Na, Mg, Ca, Sr, Ba and an organic cation, and X includes halogen, wherein n denotes an integer equal to or greater than one, and wherein one selected from the source electrode and the drain electrode is electrically connected to the light-emitting element.

The semiconductor layer may include grains, and a size of the grains may range from 10 μm to 50 μm.

In the perovskite compound, a content of A may range from 50 mol % to 300 mol % based on 100 mol % of the tin (Sn).

According to an aspect of embodiments of the present disclosure, there may be provided a method for fabricating a thin-film transistor, the method including: preparing a perovskite precursor by mixing AX₂, SnX₂ and a solvent; and coating and heat-treating the perovskite precursor on a substrate to form a semiconductor layer, wherein the semiconductor layer includes a perovskite compound represented by the following chemical formula:

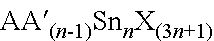

wherein A is R₁(NH₃⁺)₂ or

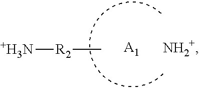

R₁ includes at least one selected from: a substituted or unsubstituted C₁₋₂₀ linear or branched alkyl group; a substituted or unsubstituted 5-membered unsaturated or aromatic ring; a substituted or unsubstituted 6-membered unsaturated or aromatic ring; a substituted or unsubstituted 5-membered unsaturated or aromatic heterocyclic group; and a substituted or unsubstituted 6-membered unsaturated or aromatic heterocyclic group, R₂ is substituted or unsubstituted C₁₋₁₀ alkyl group, A₁ includes at least one selected from: a substituted or unsubstituted 5-membered unsaturated or aromatic heterocyclic group; and a substituted or unsubstituted 6-membered unsaturated or aromatic heterocyclic group, the heterocyclic group includes at least one selected from the group consisting of N, O and S, and X includes halogen.

A mole ratio between AX₂ and SnX₂ may be 0.5:1 to 3:1.

The heat treatment may be performed at a temperature of 100° C. to 200° C.

The perovskite precursor may further include A′X, and wherein A′ may include at least one selected from Rb, Cs, K, Na, Mg, Ca, Sr, Ba, and an organic cation.

The method may further include: after the forming the semiconductor layer, forming a source electrode and a drain electrode spaced apart from each other on the semiconductor layer; forming a gate insulator on the semiconductor layer, the source electrode and the drain electrode; and forming a gate electrode on the gate insulator, wherein a channel region of the semiconductor layer and the gate electrode overlap each other in a thickness direction of the substrate.

The method may further include: prior to the forming the semiconductor layer, forming a gate electrode on the substrate; forming a gate insulator covering the gate electrode; forming a source electrode and a drain electrode spaced apart from each other on the gate insulator; and forming a semiconductor layer covering the source electrode and the drain electrode, wherein a channel region of the semiconductor layer and the gate electrode overlap each other in a thickness direction of the substrate.

The method may further include: prior to the forming the semiconductor layer, forming a gate electrode on the substrate; forming a gate insulator on the gate electrode; and after the forming the semiconductor layer, forming a source electrode and a drain electrode on the semiconductor layer.

According to an aspect of embodiments of the present disclosure, there may be provided an electronic device including: a display device to provide images; and a processor to transmit an image data signal to the display device, wherein the display device may include: a light-emitting element and a thin-film transistor, wherein the thin-film transistor may include: a substrate; a semiconductor layer on the substrate; a gate electrode that overlaps with a channel region of the semiconductor layer in a thickness direction of the substrate; a gate insulator may be between the semiconductor layer and the gate electrode to insulate (e.g., electrically insulate) the semiconductor layer from the gate electrode; and a source electrode and a drain electrode may be on a surface of the semiconductor layer, wherein the semiconductor layer may include a perovskite compound represented by the following formula:

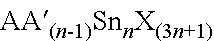

wherein A is R₁(NH₃⁺)₂ or

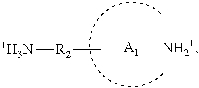

R₁ includes at least one selected from: a substituted or unsubstituted C₁₋₂₀ linear or branched alkyl group; a substituted or unsubstituted 5-membered unsaturated or aromatic ring; a substituted or unsubstituted 6-membered unsaturated or aromatic ring; a substituted or unsubstituted 5-membered unsaturated or aromatic heterocyclic group; and a substituted or unsubstituted 6-membered unsaturated or aromatic heterocyclic group, R₂ is a substituted or unsubstituted C₁₋₁₀ alkyl group, A₁ includes at least one selected from: a substituted or unsubstituted 5-membered unsaturated or aromatic heterocyclic group; and a substituted or unsubstituted 6-membered unsaturated or aromatic heterocyclic group, the heterocyclic group includes at least one selected from the group consisting of N, O and S, A′ includes at least one selected from Rb, Cs, K, Na, Mg, Ca, Sr, Ba and an organic cation, and X includes halogen, wherein n denotes an integer equal to or greater than one, and wherein one selected from the source electrode and the drain electrode is electrically connected to the light-emitting element.

According to the thin film transistor according to embodiments, excellent electron mobility and current flickering ratio can be achieved by using a tin-based perovskite compound as a semiconductor layer.

The thin film transistor of embodiments of the present disclosure can prevent or reduce oxidation of tin (Sn) and minimize or reduce the occurrence of tin (Sn) vacancies by using a tin (Sn)-based perovskite compound containing double ammonium cations as a semiconductor layer.

In embodiments, the thin film transistor of embodiments of the present disclosure can exhibit excellent stability even in the air.

The effects according to embodiments are not limited to the contents described herein, and more diverse effects are included in the present specification.

### BRIEF DESCRIPTION OF THE DRAWINGS

Features of embodiments of the present disclosure, and the methods for achieving them, will become clear with reference to the embodiments described in more detail below with the accompanying drawings. However, the present disclosure is not limited to the embodiments disclosed below, but may be implemented in various suitable different forms, and these embodiments are provided only to make the disclosure of the present disclosure complete and to fully inform those skilled in the art of the disclosure of the scope of the disclosure, and the present disclosure is defined only by the scope of the appended claims and equivalents thereof.

When elements or layers are referred to as “on” another element or layer, this includes all cases where another layer or another element is interposed directly over or in the middle of the other element. The same reference numerals refer to the same components throughout the specification. The shapes, sizes, ratios, angles, numbers, and/or the like disclosed in the drawings to explain embodiments are examples, and therefore the present disclosure is not limited to the matters illustrated.

Each feature of the various embodiments of the present disclosure may be partially or entirely combined or combined with each other, and may be technically capable of various suitable interconnections and operations. Each embodiment may be implemented independently of each other or may be implemented together in a related relationship. Example embodiments are described below with reference to the attached drawings.

The above and other aspects and features of embodiments of the present disclosure will become more apparent by describing in more detail example embodiments thereof with reference to the attached drawings, in which:

FIG. 1 is a plan view of a display device according to an embodiment of the present disclosure.

FIG. 2 is a side view of a display device according to an embodiment of the present disclosure.

FIG. 3 is a cross-sectional view showing the display panel according to embodiments of the present disclosure.

FIG. 4 is an enlarged cross-sectional view of area A of FIG. 3, showing the structure of a thin-film transistor according to a first embodiment.

FIG. 5 is an enlarged cross-sectional view of area A of FIG. 3, showing the structure of a transistor according to a second embodiment.

FIG. 6 is an enlarged cross-sectional view of area A of FIG. 3, showing the structure of a transistor according to a third embodiment.

FIG. 7 is a schematic view showing the crystal structure of a perovskite compound of the Ruddlesden-Popper phase.

FIG. 8 is a schematic view showing the crystal structure of a perovskite compound of the Dion-Jacobson phase.

FIG. 9 is a flowchart illustrating a method for fabricating a thin-film transistor according to an embodiment of the present disclosure.

FIG. 10 is a graph showing XRD (X-ray diffraction) spectra of semiconductor layers of Examples 1 to 6 fabricated according to an embodiment.

FIG. 11 is a graph showing UV-Vis absorption spectra of semiconductor layers of Examples 1, 3 and 5 fabricated according to an embodiment.

FIG. 12 is a graph showing UV-Vis absorption spectra of semiconductor layers of Examples 2, 4 and 6 fabricated according to an embodiment.

FIG. 13 is a graph showing XRD (X-ray diffraction) spectra of semiconductor layers of Examples 7 and 8 fabricated according to an embodiment.

FIG. 14 is a graph showing UV-Vis absorption spectra of semiconductor layers of Examples 7 and 8 fabricated according to an embodiment, in which the inset is a Tauc plot.

FIG. 15 is an SEM (scanning electron microscope) image of the semiconductor layer of Example 2 fabricated according to an embodiment.

FIG. 16 is an SEM (scanning electron microscope) image of the semiconductor layer of Example 7 fabricated according to an embodiment.

FIG. 17 is a graph showing transition curves of Example 2, Example 2-1 and Example 2-2 fabricated according to an embodiment.

FIG. 18 is a graph showing transition curves of Example 2-2 and Example 2-3 fabricated according to an embodiment.

FIG. 19 is a graph showing transition curves of Examples 7 and 8 fabricated according to an embodiment.

FIG. 20 is a graph showing transition curves of Comparative Example 2 fabricated according to an embodiment.

FIG. 21 is a graph showing transition curves over time of Example 2-2 fabricated according to one embodiment.

FIG. 22 is a graph showing transition curves over time of Example 7 fabricated according to an embodiment.

FIG. 23 is a graph showing transition curves over time when the thin-film transistor of Comparative Example 1 was exposed to air.

FIG. 24 is a graph showing transition curves over time when the thin-film transistor of Example 7 was exposed to air.

FIG. 25 is a graph showing transition curves over time when the thin-film transistor of Example 8 was exposed to air.

FIG. 26 is a graph showing XRD (X-ray diffraction) spectra over exposure time when the thin-film transistor of Example 7 is exposed to air.

FIG. 27 is a graph showing XRD (X-ray diffraction) spectra over exposure time when the thin-film transistor of Example 8 is exposed to air.

FIG. 28 is a block diagram of an electronic device according to an embodiment of the present disclosure.

FIG. 29 is a view showing electronic devices according to a variety of embodiments of the present disclosure.

### DETAILED DESCRIPTION

Hereinafter, example embodiments of the present disclosure will be described in more detail with reference to the accompanying drawings.

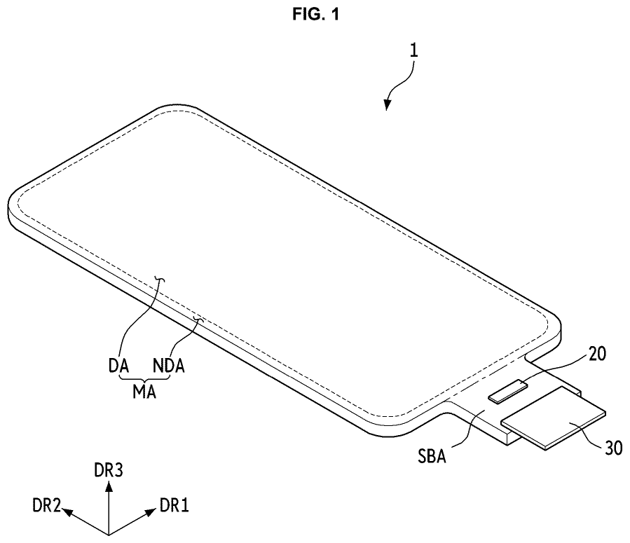

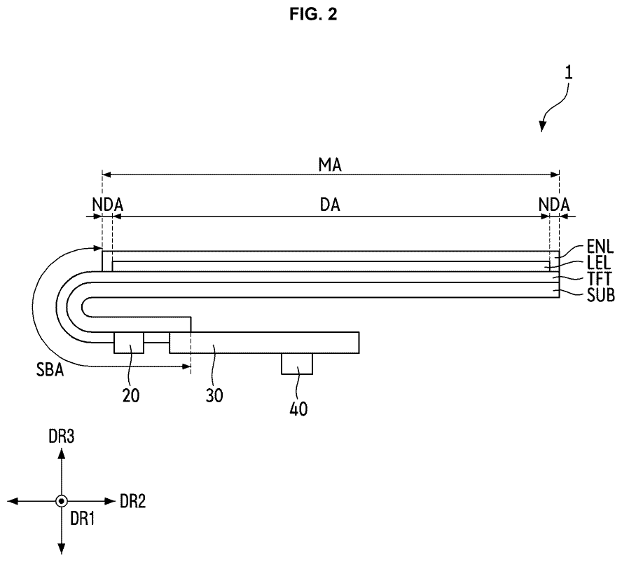

FIG. 1 is a plan view of a display device according to an embodiment of the present disclosure. FIG. 2 is a side view of a display device according to an example embodiment of the present disclosure.

Referring to FIG. 1, a display device 1 according to an embodiment of the present disclosure is to display moving images and/or still images. The display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and/or a ultra mobile PC (UMPC), as well as the display screen of various suitable products such as a television, a notebook, a monitor, a billboard and/or the Internet of Things (IoT) devices.

According to an embodiment of the present disclosure, the display device 1 may be a light-emitting display device such as an organic light-emitting display device using organic light-emitting diodes, a quantum-dot light-emitting display device including quantum-dot light-emitting layer, an inorganic light-emitting display device including an inorganic semiconductor, and/or a micro-LED display device using micro and/or nano light-emitting diodes (micro LEDs or nano LEDs). In the following description, an organic light-emitting display device is described as an example of the display device 1 according to example embodiments. It is, however, to be understood that embodiments of the present disclosure are not limited thereto.

The display device 100 includes a display panel 10, a display driver circuit 20 and a circuit board 30.

The display panel 1 may be formed in a rectangular plane having shorter sides in a first direction DR1 and longer sides in a second direction DR2 crossing (e.g., intersecting) the first direction DR1. In embodiments, the display panel 100 may have a thickness in the third direction DR3 that crosses (e.g., intersects) the first direction DR1 and the second direction DR2. Each of the corners where the shorter side in the first direction DR1 meets the longer side in the second direction DR2 may be rounded having a set or predetermined curvature or may be a right angle. The shape of the display panel 1 when viewed from the top is not limited to a quadrangular shape, but may be formed in a different polygonal shape, a circular shape, or an elliptical shape. The display panel 1 may be formed flat, but the present disclosure is not limited thereto. For example, the display panel 1 may be formed at left and right ends, and may include a curved portion having a constant (e.g., substantially constant) curvature or a varying curvature. In embodiments, the display panel 1 may be flexible so that it can be curved, bent, folded and/or rolled.

The display panel 1 may include the main area MA and a subsidiary area SBA.

The main area MA may include a display area DA where images are displayed, and a non-display area NDA around the display area DA. The display area DA may occupy most of the main area MA. The display area DA may be provided at the center of the main area MR. The non-display area NDA may be provided adjacent to the display area DA. The non-display area NDA may be on the outer side of the display area DA. The non-display area NDA may surround the display area DA. The non-display area NDA may be defined as the border of the display panel 100. A plurality of pixels PX that present images may be provided in the display area DA. The display area DA may include pixels PX to display images. For example, the display area DA may include pixel areas where the pixels PX are provided.

The subsidiary area SBA may be extended from one side of the main area MA in the first direction DR1. The length of the subsidiary area SBA in the first direction DR1 may be smaller than the length of the main area MA in the first direction DR1. The length of the subsidiary area SBA in the second direction DR2 may be less than the length of the main area MA in the second direction DR2 or may be substantially equal to it. The sub-area SBA may be bent and may be provided under the display panel 100. In embodiments, the subsidiary area SBA may overlap with the main area MA in the third direction DR3.

The display driver circuit 20 may generate signals and voltages to drive the display panel 1. The display driver circuit 20 may be implemented as an integrated circuit (IC) and may be attached to the subsidiary area SBA of the display panel 1 by a chip on glass (COG) technique, a chip on plastic (COP) technique, and/or an ultrasonic bonding. In embodiments, the display driver circuit 20 may be attached on the circuit board 30 by the chip-on-film (COF) technique.

The circuit board 30 may be attached to one end of the subsidiary area SBA of the display panel 1. Accordingly, the circuit board 30 may be electrically connected to the display panel 1 and the display driver circuit 20. The display panel 1 and the display driver circuit 20 may receive digital video data, timing signals, and driving voltages through the circuit board 30. The circuit board 30 may be a flexible printed circuit board, a printed circuit board, or a flexible film such as a chip on film.

A light-blocking layer that absorbs light incident from the outside, a buffer layer that absorbs impact from the outside, and a heat-dissipation layer that efficiently discharges heat from the display panel 100 may be further included under the display panel 100.

The light-blocking layer can block transmission of light, thereby preventing or reducing visibility of elements under the light-blocking layer from above the display panel 100. The light-blocking layer may include a light-absorbing material such as a black pigment and/or a black dye.

The buffer layer can absorb external shock to prevent or reduce damage to the display panel 100. The buffer layer may be made up of a single layer or a plurality of layers. For example, the buffer layer may be formed of a polymer resin such as polyurethane, polycarbonate, polypropylene and/or polyethylene, or may be formed of a material having elasticity such as a rubber and/or a sponge obtained by foaming a urethane-based material and/or an acrylic-based material.

The heat sink layer may include a first heat dissipation layer including graphite and/or carbon nanotubes, and a second heat dissipation layer formed of a thin metal film such as copper, nickel, ferrite and silver, which can block or reduce transmission of electromagnetic waves and have high thermal conductivity.

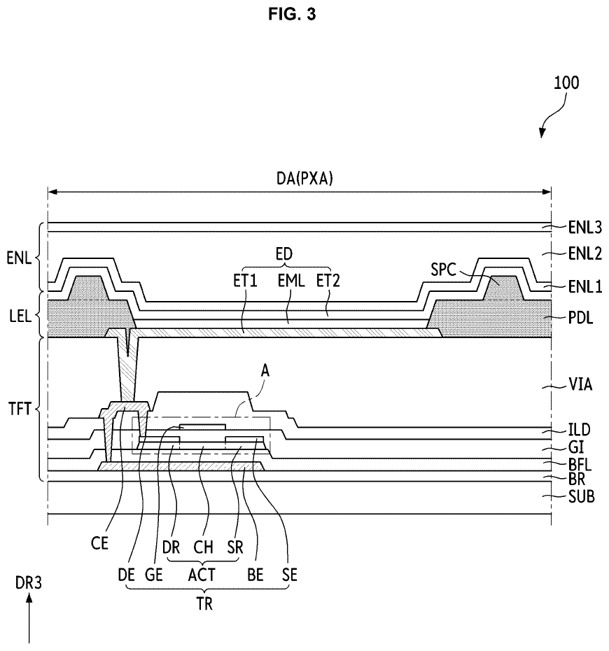

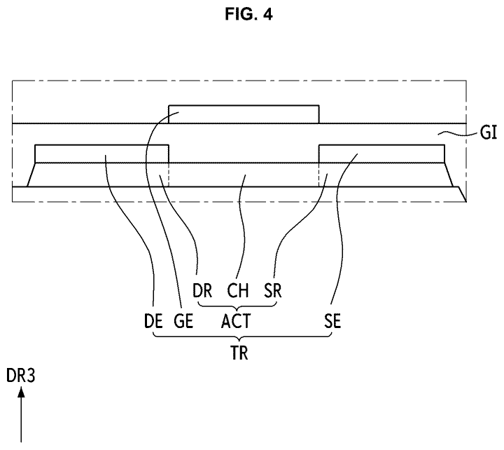

FIG. 3 is a cross-sectional view showing the display panel according to embodiments of the present disclosure. FIG. 4 is an enlarged cross-sectional view of area A of FIG. 3, showing the structure of a thin-film transistor according to a first embodiment. For example, FIG. 3 shows a portion of the display area DA of the display panel 100. FIG. 3 shows a light-emitting display panel including a light-emitting element ED (e.g., an organic light-emitting diode) as an example of the display panel 100 according to embodiments of the present disclosure.

Referring to FIG. 3, the display panel 100 may include a substrate SUB (or a base layer), a thin-film transistor layer TFT, a light-emitting element layer LEL, and an encapsulation layer ENL. The thin-film transistor layer TFT, the light-emitting element layer LEL and the encapsulation layer ENL may be on the substrate SUB such that they overlap one another. For example, in the display area DA, the thin-film transistor layer TFT, the light-emitting element layer LEL and the encapsulation layer ENL may be sequentially on the substrate SUB in the third direction DR3.

According to an embodiment of the present disclosure, the display panel 100 may further include additional elements on and/or under the encapsulation layer ENL. For example, the display panel 100 may further include at least one selected from a sensor layer (e.g., a touch sensor layer), an optical layer (e.g., a color filter layer and/or a wavelength conversion layer), and a protective layer (e.g., a protective film, an insulating layer (e.g., an electrically insulating layer), an upper substrate and/or a window). Each of the sensor layer, optical layer and/or protective layer may be over the encapsulation layer ENL and/or between the light-emitting element layer LEL and the encapsulation layer ENL.

The substrate SUB may be a base member that forms the display panel 100 and may be rigid or flexible. According to an embodiment of the present disclosure, the substrate SUB may be a substrate that includes an insulating material (e.g., an electrically insulating material) such as glass and is rigid, which may not be bendable. In embodiments, the substrate SUB may be a flexible substrate that includes polyimide and/or other insulating material (e.g., electrically insulating material) and allows deformation such as bending, folding and/or rolling, and may be bent or not bent.

The thin-film transistor layer TFT (e.g., a backplane circuit layer or a thin-film transistor layer) may be on the substrate SUB. The thin-film transistor layer TFT may include circuit elements including pixel transistors PXT and capacitors C of the pixels PX, and lines (e.g., signal lines and voltage lines).

According to an embodiment of the present disclosure, the transistors TR may be formed using oxide semiconductor. In embodiments, the transistors TR may be formed using a material having semiconductor properties. The active layers ACT of the transistors TR may be provided in the same layer (e.g., on top of a buffer layer BFL) within the thin-film transistors layer TFT.

The thin-film transistor layer TFT may include a plurality of conductive layers (e.g., electrically conductive layers) and at least one semiconductor layer on the substrate SUB (or a barrier layer BR). In embodiments, the thin-film transistor layer TFT may further include a plurality of insulating layers (e.g., electrically insulating layers) and/or insulating patterns (e.g., electrically insulating patterns) on the substrate SUB (or the barrier layer BR).

Patterns included in the conductive layers of the thin-film transistor layer TFT may include electrodes that form circuit elements of the thin-film transistor layer TFT, conductive patterns connected to the circuit elements, and/or lines, and/or the like. Patterns included in each conductive layer of the thin-film transistor layer TFT (e.g., electrodes, conductive patterns and/or lines of each conductive layer) may include at least one conductive material (e.g., electrically conductive material). For example, patterns included in each conductive layer of the thin-film transistor TFT layer may include at least one selected from copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg) and other metals, an alloy thereof, and/or other conductive material (e.g., electrically conductive material). According to an embodiment of the present disclosure, the patterns included in the same conductive layer may be formed concurrently (e.g., simultaneously) using the same conductive material.

Patterns included in the semiconductor layer of the thin-film transistor layer TFT may include active layers ACT of transistors provided in the thin-film transistor layer TFT. According to an embodiment of the present disclosure, the active layers ACT of the pixel transistors PXT and circuit transistors may be formed together using the same semiconductor material (e.g., a perovskite compound). Accordingly, the active layers ACT of the transistors TR and the circuit transistors may be provided in the same layer and may include the same semiconductor material.

The insulating layers and/or insulating patterns of the thin-film transistor layer TFT may include a barrier layer BR, a buffer layer BFL, a gate insulator GI, an interlayer dielectric layer ILD and a planarization layer VIA sequentially on the substrate SUB along the third direction DR3. Each of the insulating layers and/or insulating patterns of the thin-film transistor layer TFT may include an inorganic insulating material (e.g., an inorganic electrically insulating material) or an organic insulating material (e.g., an organic electrically insulating material), and may be made up of a single layer or a plurality of layers.

According to an embodiment of the present disclosure, at least one of the insulating layers of the thin-film transistor layer TFT may be over the entire display area DA. For example, the barrier layer BR, the buffer layer BFL, the interlayer dielectric layer ILD and the planarization layer VIA may be over the entire display area DA.

Each layer of the structure of the thin-film transistor layer TFT will now be further described. First, the barrier layer BR may be provided on the substrate SUB. The barrier layer BR may include at least one inorganic insulating layer including an inorganic insulating material (e.g., an inorganic electrically insulating material such as, for example, silicon nitride (SiNx), silicon oxide (SiOx), silicon oxynitride (SiON), titanium oxide (TiOx), aluminum oxide (AlxOy), and/or other inorganic insulating materials (e.g., inorganic electrically insulating materials). The barrier layer BR can protect the pixels PX from moisture permeating through the substrate SUB, which is vulnerable to moisture permeation. The barrier layer BR may be eliminated.

A first conductive layer (e.g., a first electrically conductive layer such as, for example, a lower conductive layer) including a bottom electrode BE (or a light-blocking layer) of at least one transistor may be on the barrier layer BR (or substrate SUB). For example, the bottom electrode BE (or the light-blocking layer) of the transistor TR may be provided on the barrier layer BR. The bottom electrode BE may be under the active layer ACT such that it overlaps with the channel region CH of the transistor TR. According to embodiments of the present disclosure, the bottom electrode BE may also overlap with at least parts of the source region SR and the drain region DR of the transistor TR, but the present disclosure is not limited thereto. Each of the patterns of the first conductive layer including the bottom electrode BE may include at least one conductive material (e.g., electrically conductive material) and may be made up of a single layer or a plurality of layers.

According to embodiments of the present disclosure, the bottom electrode BE may be electrically connected to one electrode of the transistor TR (e.g., a connection electrode CNE) and may be used as an electrode to adjust the characteristics of the transistor TR. For example, the bottom electrode BE may be electrically connected to the connection electrode CNE of the transistor TR. When the bottom electrode BE is electrically connected to one electrode of the transistor TR, the bottom electrode BE may also be regarded as an element included in the transistor TR. By providing the bottom electrode BE under the active layer ACT, it is possible to block or reduce entrance of external light into the channel region CH of the transistor TR. According to an embodiment of the present disclosure where the transistors of the thin-film transistor layer TFT do not include the bottom electrode BE or the light-blocking layer, the first conductive layer may be eliminated.

The buffer layer BFL may be on the barrier layer BR and the bottom electrode BE. The buffer layer BFL may include at least one inorganic insulating layer (e.g., an inorganic electrically insulating layer) including an inorganic insulating material (e.g., an inorganic electrically insulating material such as, for example, silicon nitride (SiNx), silicon oxide (SiOx), silicon oxynitride (SiON), titanium oxide (TiOx), aluminum oxide (AlxOy), and/or other inorganic insulating materials (e.g., inorganic electrically insulating materials)).

The buffer layer BF may include an insulating material (e.g., an electrically insulating material) suitable as a barrier material that can prevent or reduce diffusion of oxygen, hydrogen, and/or the like. The buffer layer BFL may include other insulating materials (e.g., electrically insulating materials) capable of suitably or appropriately blocking or reducing transmission of oxygen, hydrogen and/or moisture, in addition to a silicon nitride film containing silicon nitride (SiNx) and a silicon oxide film containing silicon oxide (SiOx).

The active layer ACT may include the channel region CH, the source region SR and the drain region DR. The channel region CH may overlap with the gate electrode GE in the third direction DR3 when viewed from the top, and may be between the source region SR and the drain region DR. The source region SR and the drain region DR may be on the opposite sides of the channel region CH, respectively, and may be spaced apart from each other with the channel region CH therebetween. The source region SR and the drain region DR (or a part of each of the source region SR and the drain region DR) may not overlap with the gate electrode GE when viewed from the top. The carrier concentration (e.g., electron concentration) of the source region SR and the drain region DR may be higher than the carrier concentration of the channel region CH.

A source electrode SE may be on the source region SR, and a drain electrode DE may be on the drain region DR. The source electrode SE and the drain electrode DE may not overlap with the gate electrode GE when viewed from the top. Each of the source electrode SE and the drain electrode DE may be electrically connected to the active layer ACT in such a way that it is in contact with the active layer ACT. When electric current is applied to the transistor TR, the interface where the source region SR of the active layer ACT and the source electrode SE are in contact with each other may be conductive (e.g., electrically conductive). When electric current is applied to the transistor TR, the interface where the drain region DR of the active layer ACT and the drain electrode DE are in contact with each other may be conductive (e.g., electrically conductive). When electric current is applied to the transistor TR, the electric current may flow through the interface between the drain region DR of the active layer ACT and the drain electrode DE, the channel region CH of the active layer ACT, and the interface between the source region SR of the active layer ACT and the source electrode SE.

According to an embodiment of the present disclosure, the active layers ACT may include a perovskite compound. The perovskite compound will be further described in more detail herein.

Each of the drain electrode DE and the source electrode SE may independently include at least one selected from copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg) and other metals, an alloy thereof, and/or other conductive material (e.g., electrically conductive material).

According to some embodiments, the active layers ACT of some of the transistors provided in the thin-film transistor layer TFT may be on the buffer layer BFL.

According to embodiments of the present disclosure, at least one transistor TR may be provided in each pixel area PXA. Accordingly, a plurality of transistors TR may be provided in the display area DA.

The gate insulator GI may be on the active layer ACT. For example, the gate insulator GI may be on the buffer layer BFL and cover the active layers ACT, the drain electrode DE, and the source electrode SE. The gate insulator GI may include at least one inorganic insulating layer (e.g., inorganic electrically insulating layer) including an inorganic insulating material (e.g., inorganic electrically insulating material such as, for example, silicon nitride (SiNx), silicon oxide (SiOx), silicon oxynitride (SiON), titanium oxide (TiOx), aluminum oxide (AlxOy), and/or other inorganic insulating materials (e.g., inorganic electrically insulating materials)).

A second conductive layer (e.g., a second electrically conductive layer such as, for example, a gate conductive layer) including gate electrodes GE may be on the gate insulator GI. For example, the gate electrode GE of the transistor TR may be on the gate insulator GI covering the channel region CH of the transistor TR. Each of the patterns of the second conductive layer including the gate electrodes GE may include at least one conductive material (e.g., electrically conductive material) and may be made up of a single layer or a plurality of layers.

The interlayer dielectric layer ILD may be on the buffer layer BFL, the semiconductor layer including the active layers ACT, the gate insulator GI and the second conductive layer including gate electrodes GE. For example, the interlayer dielectric layer ILD may be provided on the buffer layer BFL to cover the semiconductor layer, the gate insulator GI and the patterns of the second conductive layer. The interlayer dielectric layer ILD may include at least one inorganic insulating layer (e.g., inorganic electrically insulating layer) containing an inorganic insulating material (e.g., an inorganic electrically insulating material).

A third conductive layer (e.g., a third electrically conductive layer) including conductive patterns (e.g., electrically conductive patterns) electrically connected to the connection electrode CNE and/or at least some of the transistors TR may be on the interlayer dielectric layer ILD. For example, the third conductive layer may include the connection electrode CNE of the transistor TR. Each of the patterns of the third conductive layer may include at least one conductive material (e.g., electrically conductive material) and may be made up of a single layer or a plurality of layers.

The connection electrode CNE of the transistor TR may also be electrically connected to the drain electrode DE of the transistor TR through the interlayer dielectric layer ILD. According to embodiments of the present disclosure, the connection electrode CNE of the transistor TR may also be electrically connected to the bottom electrode BE of the transistor TR through the interlayer dielectric layer ILD and the buffer layer BFL.

The planarization layer VIA may be over the transistor TR. For example, the planarization layer VIA may be on the interlayer dielectric layer ILD and the third conductive layer. The planarization layer VIA may include at least one organic insulating layer (e.g., organic electrically insulating layer) containing an organic insulating material (e.g., an organic electrically insulating material such as, for example, an acrylic resin, an epoxy resin, a phenolic resin, a polyamide resin, a polyimide resin, and/or other organic insulating materials (e.g., organic electrically insulating materials)). The planarization layer VIA may or may not include an inorganic insulating layer (e.g., an inorganic electrically insulating layer). A surface (e.g., upper surface) of the planarization layer VIA may be substantially flat.

The light-emitting element layer LEL may be on the thin-film transistor layer TFT. For example, the light-emitting element layer LEL may be on the planarization layer VIA and may be provided at least in the display area DA.

The light-emitting element layer LEL may include alight-emitting element ED of each of the pixels PX. For example, the light-emitting element layer LEL may include a pixel-defining layer PDL (also referred to as a “bank”) that partitions the emission area of each of the pixels PX, and a light-emitting element ED provide in each emission area. According to embodiments of the present disclosure, the light-emitting element layer LEL may further include a spacer SPC on a portion of the pixel-defining layer PDL.

Each of the light-emitting elements EL may include a first electrode ET1 provided in each emission area, and an emissive layer EML and a second electrode ET2 sequentially on the first electrode ET1. The first electrode ET1 of the light-emitting element ED may be electrically connected to at least one transistor TR included in that pixel PX through the planarization layer VIA.

The first electrode ET1 of the light-emitting element ED may be a single-layer or multi-layer electrode containing at least one conductive material (e.g., electrically conductive material). According to embodiments of the present disclosure, the display panel 100 may be a top-emission display panel. The first electrode ET1 may include a reflective electrode layer containing at least one material selected from among aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir) and chromium (Cr), and/or other reflective conductive material (e.g., reflective electrically conductive material).

The emissive layer EML of each of the light-emitting elements ED may include a high-molecular substance (e.g., a high-molecular weight substance) and/or a low-molecular substance (e.g., a low-molecular weight substance). Light emitted from the emissive layer EML may contribute to displaying images.

Although FIG. 3 shows the display panel 100 in which the emissive layer EML of the light-emitting element ED is individually formed in the respective pixel area PXA, embodiments of the present disclosure are not limited thereto. For example, the display panel 100 may include light-emitting elements in a tandem structure including the emissive layer EML formed as a common film over the entire display area DA.

The second electrode ET2 of the light-emitting element ED may include a conductive material (e.g., an electrically conductive material). According to embodiments of the present disclosure, the second electrode ET2 may be a common layer formed over the entire display area DA to cover the emissive layer EML and the pixel-defining layer PDL. According to embodiments of the present disclosure, the display panel 100 may be a top-emission display panel, and the second electrode ET2 may include a transparent or translucent electrode layer.

In the top-emission organic light-emitting diode, the second electrode ET2 may be formed of a transparent conductive material (TCP) such as ITO and IZO that can transmit light, or a semi-transmissive conductive material such as magnesium (Mg), silver (Ag) and/or an alloy of magnesium (Mg) and silver (Ag). When the second electrode ET2 is made of a semi-transmissive conductive material, the light extraction efficiency of each of the light-emitting elements ED can be increased by using microcavities.

When the second electrode ET2 is made of a semi-transmissive conductive material, the light extraction efficiency of each of the light-emitting elements ED can be increased by using microcavities.

The pixel-defining layer PDL may have openings associated with the respective emission areas and may surround the emission areas. For example, the pixel-defining layer PDL may cover an edge of the first electrode ET1 of the light-emitting element ED, and may include an opening that exposes the remaining portion of the first electrode ET1. The area where the exposed portion of the first electrode ET1 and the emissive layer EML overlap each other may be the emission area of each pixel PX. According to embodiments of the present disclosure, the pixel-defining layer PDL may include an organic material. The pixel-defining layer may include a light-blocking material. The pixel-defining layer PDL includes a base resin and a colorant. The base resin may include at least one selected from: a cardo resin, an epoxy resin, an acrylate resin, a siloxane resin, and polyimide. The colorant may be selected from a carbon pigment, a metal oxide pigment, and an organic pigment. For example, the carbon pigment may be selected from, but is not limited to, carbon black, carbon nanotubes, titanium black, vertically aligned nanotube arrays (VANTA) black, and/or the like. For example, the metal oxide pigment may be, but is not limited to, titanium black (TiNxOy), and/or Cu—Mn—Fe black pigment. For example, the organic pigment may be, but is not limited to, lactam black, perylene black, and/or aniline black. For another example, the colorant may be a mixture of two or more types (or kinds) of pigments and/or dyes having different colors. It should be understood, however, that embodiments of the present disclosure are not limited thereto.

The spacer SPC may be on a part of the pixel-defining layer PDL. The spacer SPC may include at least one organic insulating layer (e.g., organic electrically insulating layer) containing an organic insulating material. The spacer SPC may include the same material as the pixel-defining layer PDL or may include a different material from the pixel-defining layer PDL. The pixel-defining layer PDL and the spacer SPC may be formed sequentially via the respective mask processes, or may be formed concurrently (e.g., simultaneously) and/or integrally using a halftone mask.

The encapsulation layer ENL may be on the light-emitting element layer LEL. The encapsulation layer ENL may cover the light-emitting element layer LEL in the display area DA and may be extended to the non-display area NDA to be in contact with the thin-film transistor layer TFT. The encapsulation layer ENL can block or reduce the permeation of oxygen and/or moisture into the light-emitting element layer LEL and can alleviate or reduce electrical and/or physical shock on the thin-film transistor layer TFT and the light-emitting element layer LEL.

According to an embodiment of the present disclosure, the encapsulation layer ENL may include a first encapsulation layer ENL1, a second encapsulation layer ENL2, and a third encapsulation layer ENL3 sequentially on the emission material layer LEL. Each of the first encapsulation layer ENL1 and the third encapsulation layer ENL3 may be an inorganic encapsulation layer containing an inorganic material. The second encapsulation layer ENL2 may be an organic encapsulation layer containing an organic material.

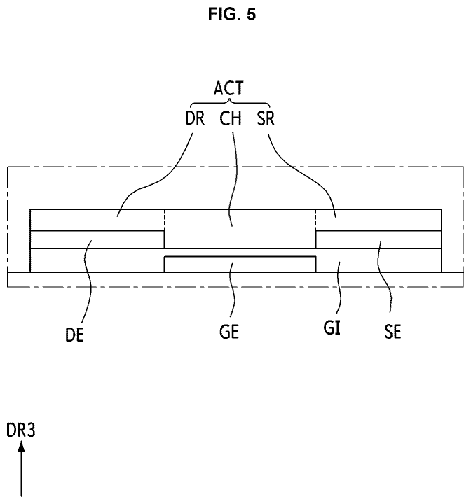

FIG. 5 is an enlarged cross-sectional view of area A of FIG. 3, showing the structure of a transistor according to a second embodiment. The transistor according to the embodiment of FIG. 5 is substantially identical to the transistor TR according to the first embodiment shown in FIG. 4 except that a gate electrode GE is provided on a buffer layer BFL, a gate insulator GI is provided on the gate electrode GE, and active layers ACT, a drain electrode DE and a source electrode SE are provided on the gate insulator GI; and, therefore, redundant descriptions thereof may not be repeated herein.

Referring to FIG. 5, the gate electrode GE may be on the buffer layer BFL, the gate insulator GI may be on the gate electrode GE, and the gate insulator GI may cover the gate electrode GE. The gate electrode GE may be provided such that it overlaps with the channel region CH of the active layer ACT in the third direction DR3.

The drain electrode DE and the source electrode SE may be on the gate insulator GI. The drain electrode DE and the source electrode SE may be spaced apart from each other such that they do not overlap with the gate electrode GE in the third direction DR3 when viewed from the top. The drain electrode DE may be electrically connected to the connection electrode CNE.

The active layer ACT may be on the gate insulator GI, and the active layer ACT may cover the drain electrode DE and the source electrode SE. The channel region CH of the active layer ACT may overlap with the gate electrode GE in the third direction DR3 when viewed from the top, and may be between the source region SR and the drain region DR. The region of the active layer ACT covering the drain electrode DE may become the drain region DR, and the region of the active layer ACT that covers the source electrode SE may become the source region SR.

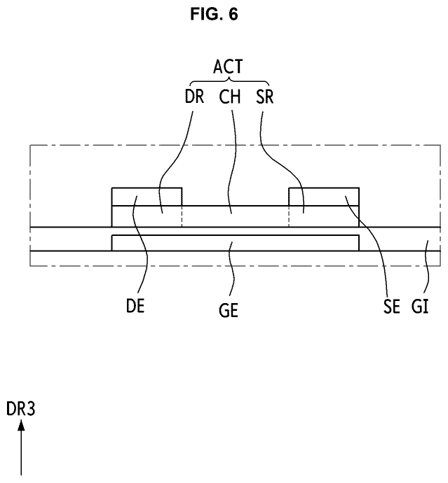

FIG. 6 is an enlarged cross-sectional view of area A of FIG. 3, showing the structure of a transistor according to a third embodiment. The transistor according to the embodiment of FIG. 6 is substantially identical to the transistor TR according to the first embodiment shown in FIG. 5 except that a drain electrode DE and a source electrode SE are on an active layer ACT; and, therefore, redundant descriptions thereof may not be repeated herein.

Referring to FIG. 6, a gate electrode GE may be provided on a buffer layer BTL. The gate electrode GE may be provided such that it overlaps with the active layer ACT in the third direction DR3. The gate insulator GI may be provided over the gate electrode GE and cover the gate electrode GE.

The active layer ACT may be on the gate insulator GI. The drain electrode DE may be provided on the drain region DR of the active layer ACT, and the source electrode SE may be provided on the source region SR of the active layer ACT. In the active layer ACT, the drain region DR and the source region SR may be spaced apart from each other with the channel region CH between the drain region DR and the source region SR. The drain electrode DE may be electrically connected to the connection electrode CNE.

The active layer ACT may be referred to as a semiconductor layer.

Tin (Sn) is used in various suitable ways as an optoelectronic device because it is harmless (e.g., relatively harmless) to the human body and the environment compared to lead (Pb), and its electrical characteristics are similar to those of lead. However, tin may be oxidized by oxygen in the air, which can deteriorate its electrical characteristics. Therefore, a technique to prevent or reduce the oxidation of tin (Sn) is desired or required.

When a thin film is formed with a perovskite compound containing tin (Sn), a large amount of tin vacancies may occur. Such tin vacancies may increase an amount of holes by generating a shallow trap state in the valence band. A perovskite thin film having an increased amount of holes may exhibit conductor properties rather than semiconductor properties, and thus may not be suitable appropriate to be used in a transistor.

According to embodiments of the present disclosure, the perovskite compound can prevent or reduce the oxidation of tin (Sn) and can suppress or reduce occurrence of tin (Sn) vacancies by containing a diammonium cation.

The active layer ACT may include a perovskite compound represented by Chemical Formula 1 below:

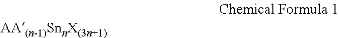

where A may be R₁(NH₃⁺)₂ or

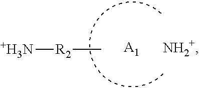

R₁ may include at least one selected from: a C₁₋₂₀ linear or branched alkyl group which may be substituted; a 5-membered unsaturated or aromatic ring which may be substituted; a 6-membered unsaturated or aromatic ring which may be substituted; a 5-membered unsaturated or aromatic heterocyclic group which may be substituted; and a 6-membered unsaturated or aromatic heterocyclic group which may be substituted, R₂ may be a C₁₋₁₀ alkyl group which may be substituted, A₁ may include at least one selected from: a 5-membered unsaturated or aromatic heterocyclic group which may be substituted; and a 6-membered unsaturated or aromatic heterocyclic group which may be substituted, the heterocyclic group may include at least one selected from the group consisting of N, O and S, A′ may include at least one selected from Rb, Cs, K, Na, Mg, Ca, Sr, Ba and an organic cation, and X may include halogen, where n denotes an integer equal to or greater than 1.

R₁ may include C₁₋₂₀ alkyl group.

R₁ may include C₂ₘ alkyl group, where m may be an integer from 1 to 10.

C₂ₘ alkyl group may mean an alkyl group having an even number of carbons.

When R₁ is a linear alkyl group and has an even number of carbons, the crystallinity of the perovskite compound can be further improved.

A₁ may include a 6-membered unsaturated or aromatic heterocyclic group, which may be substituted.

R₁(NH₃⁺)₂ may include, but is not limited to, at least one selected from: dimethyl propane diammonium (DMePDA); 1,3-propane diammonium (PDA); 1,4-butane diammonium (BDA); 1,5-pentane diammonium (PeDA); 1,6-hexane diammonium (HDA); 1,7-heptane diammonium (HepDA); 1,8-octane diammonium (ODA); 1,9-nonane diammonium (NDA); 1,10-decane diammonium; and 1,12-dodecane diammonium.

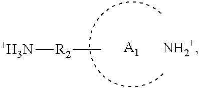

may include, but is not limited to, at least one selected from: 3-(aminomethyl)piperidinium (3AMP); 4-(aminomethyl)piperidinium (4AMP); 1,4-phenylene dimethane ammonium (PhDMA); o-cyclohexanedimethanammonium (1,2-cyclohexanedimethanammonium, o-CyHDMA); m-cyclohexanedimethanammonium (1,3-cyclohexanedimethanammonium, m-CyHDMA); p-cyclohexanedimethanammonium (1,4-cyclohexanedimethanammonium, p-CyHDMA); trans-p-cyclohexanediammonium (trans-1,4-cyclohexanediammonium, trans-p-CyHDASnI₄); (1s,2s)-(+)-1,2-cyclohexanediammoium ((1s,2s)-(+)-o-CyHDA); and 1,4-benzene diammonium (BDI).

A′ may include at least one selected from Rb, Cs, K, Na, Mg, Ca, Sr, Ba, and an organic cation. The organic cation may be methylammonium and/or formamidinium.

The value of n may be 1. When n is 1, the Chemical Formula 1 may be ASnX₄.

ASnX₄ may have a two-dimensional structure. AA′₍ₙ₋₁₎SnₙX₍₃ₙ₊₁₎ may be a two-dimensional/three-dimensional structure. While a monovalent cation (A′) allows for easy carrier transport, hole mobility may decrease in a two-dimensional structure. Therefore, if a monovalent cation (A′) is added to a diammonium cation (A), structural stability may decrease.

X may be at least one selected from fluorine (F), chlorine (CI), bromine (Br), and iodine (I).

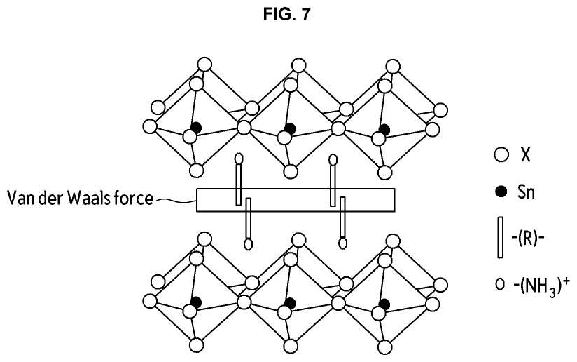

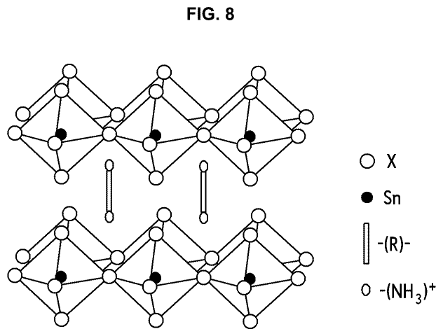

FIG. 7 is a schematic view showing the crystal structure of a perovskite compound of the Ruddlesden-Popper phase. FIG. 8 is a schematic view showing the crystal structure of a perovskite compound of the Dion-Jacobson phase.

Referring to FIGS. 7 and 8, both the Ruddlesden-Popper phase (RP-phase) and the Dion-Jacobson phase (DJ-phase) are structures in which ammonium groups of organic ammonium ions between octahedral layers of SnₙX₃ₙ₊₁ form hydrogen-bonds with the octahedral layers. The RP phase uses organic ammonium ions each having one ammonium group, where one ammonium group forms hydrogen-bond with the octahedral layers and the remaining hydrocarbon groups (R) are bonded by van der Waals forces. The DJ-phase uses organic ammonium ions each having two ammonium groups, each of which may form a hydrogen-bond with an octahedral layer. For example, one organic ammonium ion including two ammonium groups may bond with two octahedral layers and enhance the bonding force between the octahedral layers. The DJ-phase can reduce van der Waals tunneling gap which may exist in the RP-phase. In the RP-phase, the octahedral layers may be connected by van der Waals force by the hydrocarbon groups (R) of ammonium ions of ammonium cations each bonded to the octahedral layers. In the DJ-phase, a diammonium cation is bonded to two octahedral layers, and the diammonium cation between the octahedral layers may be formed as an elemental bond (e.g., a chemical bond such as, for example, a covalent bond). Perovskite including diammonium cations including two ammonium groups can further enhance the structural stability of the crystal structure.

According to embodiments of the present disclosure, the thin-film stability of the thin-film transistor TR can be improved by applying the active layer ACT containing the perovskite compound including diammonium cations.

According to embodiments of the present disclosure, the thin-film transistor TR including the perovskite compound can exhibit excellent stability even in the air and can have high electron mobility and an excellent on-off ratio (e.g., an excellent current on-off ratio (e.g., of the thin-film transistor)).

The electron mobility may be equal to or less than 10 cm²/Vs.

The current on-off ratio may be 10 to 10⁷.

The active layer ACT may have a plurality of grains. The grains may be formed as atoms, and/or the like, are provided regularly.

In embodiments, the grain size may mean the average grain size and/or the maximum grain size among the grain sizes.

The grain size of the active layer ACT may range from 10 μm to 50 μm.

If the grain size of the active layer ACT is less than 10 μm, the grain boundary between the grains may increase. The permeation of oxygen increases through the increased grain boundary, which may increase the oxidation degree of the perovskite compound, and/or the hole mobility of the active layer ACT may decrease.

If the grain size of the active layer ACT is greater than 50 μm, the active layer ACT may exhibit conductor properties (e.g., electrical conductor properties) rather than semiconductor properties.

The thickness of the active layer ACT may range from 1 nm to 100 nm. In embodiments, the thickness of the active layer ACT may range from 30 nm to 80 nm. Because the active layer ACT may be formed to have a small thickness, it can be applied to rigid devices as well as flexible devices.

If the thickness of the active layer ACT is less than 1 nm, it may be difficult to evenly apply it on the substrate. If the thickness of the active layer ACT is greater than 100 nm, it may hold charges too much.

In the perovskite compound represented by Chemical Formula 1, the content of A may range from 50 mol % to 300 mol % based on 100 mol % of tin (Sn). In embodiments, the content of A may range from 100 mol % to 200 mol % based on 100 mol % of tin (Sn). If the content of A is less than 50 mol % based on 100 mol % of tin (Sn), the stability of the crystal structure may deteriorate due to a lack of diammonium cations connecting between the octahedral layers. If the content of A is greater than 300 mol % based on 100 mol % of tin (Sn), the on-current as well as the off-current may be lowered because too many diammonium cations combine.

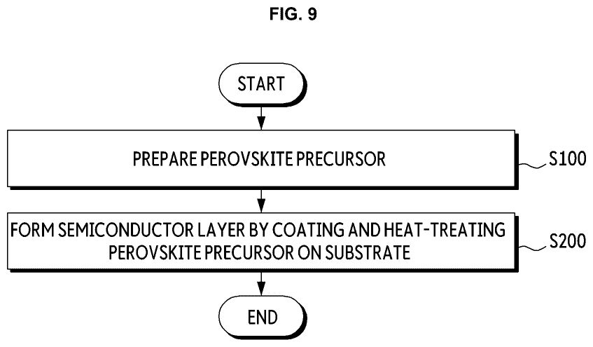

FIG. 9 is a flowchart illustrating a method for fabricating a thin-film transistor according to an embodiment of the present disclosure.

First, a perovskite precursor may be prepared (step S100).

The perovskite precursor may be prepared by mixing AX₂, SnX₂, and a solvent.

Stirring may be performed at a temperature between the room temperature and 100° C. to completely (e.g., substantially completely) dissolve AX₂ and SnX₂ in the solvent.

AX₂ may include, but is not limited to, at least one selected from: dimethyl propane diammonium diiodide (DMePDAI₂); 1,3-propane diammonium diiode (PDAI₂); 1,4-butane diammonium diiode (BDAI₂); 1,5-propane diammonium diiode (PeDAI₂); 1,6-hexane diammonium diiode (HADI₂); 1,7-heptane diammonium diiode (HepDAI₂); 1,8-octane diammonium diiode (ODAI₂); 1,9-nonane ammonium diiode (NDAI₂); 1,10-decane ammonium diiode; 1,12-dodecane diammonium diiode; 3-(amino methyl)piperidinium diiode (3AMPI₂); 4-(aminomethyl)piperidinium diiode (4AMPI₂); 1,4-phenylene dimethane ammonium diiode (PhDMAI₂); o-cyclohexane dimethane ammonium diiode (1,2-cyclohexane dimethane ammonium diiode (o-CyHDMAI₂); m-cyclohexane dimethane ammonium diiodine (1,3-cyclohexane dimethane ammonium diiode (m-CyHDMAI₂); p-cyclohexane dimethane ammonium diiode (1,4-cyclohexane dimethane ammonium diiode (p-CyHDMAI₄); trans-p-cyclohexane diammonium diiode (trans-1,4-cyclohexane diammonium diiode (trans-p-CyHDAI₄); (1s,2s)-(+)-1,2-cyclohexane diammonium diiode ((1s,2s)-(+)-o-CyHDAI₂); and 1,4-benzene diammonium diiode (BDII₂).

Although iodine (I) is disclosed as the halide ion of AX₂, the present disclosure is not limited thereto. In addition or alternatively to iodine, halide ions containing chlorine, bromine, and fluorine may be used.

The solvent may include, but is not limited to, at least one selected from: dimethyl formamide (DMF), dimethyl sulfoxide (DMSO), tetrahydrofuran (THF), dichloromethane (DCM), isopropyl alcohol (IPA), dimethylacetamide (DMA), acetonitrile, and hexamethylphosphoramide.

The mole ratio between AX₂ and SnX₂ may be 0.5:1 to 3:1. In embodiments, the mole ratio between AX₂ and SnX₂ may be 1:1 to 2:1. If the mole ratio between AX₂ and SnX₂ is less than 0.5:1, the stability of the crystal structure may be deteriorated due to a lack of diammonium cations connecting between the octahedral layers. If the mole ratio between AX₂ and SnX₂ is greater than 3:1, the on-current as well as the off-current may be lowered because too many diammonium cations combine.

The perovskite precursor may further include A′X, and A′ may include at least one selected from Rb, Cs, K, Na, Mg, Ca, Sr, Ba, and an organic cation.

Subsequently, a semiconductor layer may be formed by coating and heat-treating the perovskite precursor on the substrate (step S200).

The coating may be at least one selected from spin coating, bar coating, slot coating, dip coating, spray coating, gravure inkjet coating, dispensing coating, flexography, and screen coating.

Heat treatment may be performed at a temperature of 100° C. to 200° C.

If the heat treatment temperature is lower than 100° C., grains may not be sufficiently formed, which may result in deterioration of electrical properties. If the heat treatment temperature is higher than 200° C., grains may become too large, causing the semiconductor layer to exhibit conductor properties (e.g., electrical conductor properties) rather than semiconductor properties.

In order to fabricate the thin-film transistor TR according to the first embodiment of FIG. 4, the method may further include: after the forming the semiconductor layer ACT (step S100), forming a source electrode SE and a drain electrode DE on the semiconductor layer ACT such that they are spaced apart from each other; forming a gate insulator GI on the semiconductor layer ACT, the source electrode SE and the drain electrode DE; and forming a gate electrode GE on the gate insulator GI. The channel region CH of the semiconductor layer ACT and the gate electrode GE may overlap each other in the thickness direction DR3 of the substrate SUB.

In order to fabricate the thin-film transistor TR according to the second embodiment of FIG. 5, the method may further include: prior to the forming the semiconductor layer ACT (step S100), forming a gate electrode GE on a substrate SUB; forming a gate insulator GI covering the gate electrode GE; forming a source electrode SE and a drain electrode DE spaced apart from each other on the gate insulator GI; and forming a semiconductor layer ACT covering the source electrode SE and the drain electrode DEVICE. The channel region CH of the semiconductor layer ACT and the gate electrode GE may overlap each other in the thickness direction DR3 of the substrate SUB.

In order to fabricate the thin-film transistor TR according to the third embodiment of FIG. 6, the method may further include: prior to the forming the semiconductor layer ACT (step S100), forming a gate electrode GE on a substrate SUB; and forming a gate insulator GI on the gate electrode GE, and may further include, after the forming the semiconductor layer ACT (step S100), forming a source electrode SE and a drain electrode DE on the semiconductor layer ACT.

The gate electrode GE may be formed using the above-listed materials. A process for forming the gate electrode GE is not particularly limited herein.

The gate insulator GI may be formed using the above-listed materials. A process for forming the gate insulator GI is not particularly limited herein.

The source electrode SE and the drain electrode DE may be formed using the above-listed materials. A process for forming the source electrode SE and the drain electrode DE is not particularly limited herein.

Hereinafter, embodiments of the present disclosure will be described in more detail. It should be understood that the following embodiments of the present disclosure are merely examples and are not intended to limit the scope of the present disclosure.

### 1. Preparation of Semiconductor Layer Comprising Perovskite Compound

### 1) Example 1

In a glove box filled with nitrogen, 100 mol of propane diammonium diiodide (PDAI₂) and 100 mol of SnI₂ as AX₂ were mixed with a solvent in which DMF and DMSO were mixed at a ratio of 4:1. The mixed solution was stirred at a temperature of 60° C. and a speed of 250 rpm for 3 hours to prepare a perovskite precursor solution.

The perovskite precursor solution was applied onto a Si/SiO₂ substrate having a thickness of 100 nm and the width of 1.5×1.5 cm and then spin coating was conducted at a speed of 4,000 rpm for thirty seconds. Subsequently, the substrate was annealed at a temperature of 150° C. for ten minutes to form a semiconductor layer.

A mask in the shape of a source electrode and a drain electrode was formed on the substrate on which the semiconductor layer has been formed, and then a 40-nm-thick gold (Au) electrode was formed in a thermal evaporation apparatus. The mask was removed, and then a thin-film transistor was fabricated.

### 2) Example 2

A semiconductor layer and a thin-film transistor substantially identical to those of Example 1 were fabricated in substantially the same manner as in Example 1 except that butane diammonium diiodide (BDAI₂) was used instead of propane diammonium diiodide (PDAI₂) as AX₂.

### 3) Example 3

A semiconductor layer and a thin-film transistor substantially identical to those of Example 1 were fabricated in substantially the same manner as in Example 1 except that pentane diammonium diiodide (PeDAI₂) was used instead of propane diammonium diiodide (PDAI₂) as AX₂.

### 4) Example 4

A semiconductor layer and a thin-film transistor substantially identical to those of Example 1 were fabricated in substantially the same manner as in Example 1 except that hexane diammonium diiodide (HDAI₂) was used instead of propane diammonium diiodide (PDAI₂) as AX₂.

### 5) Example 5

A semiconductor layer and a thin-film transistor substantially identical to those of Example 1 were fabricated in substantially the same manner as in Example 1 except that heptane diammonium diiodide (HepDAI₂) was used instead of propane diammonium diiodide (PDAI₂) as AX₂.

### 6) Example 6

A semiconductor layer and a thin-film transistor substantially identical to those of Example 1 were fabricated in substantially the same manner as in Example 1 except that octane diammonium diiodide (ODAI₂) was used instead of propane diammonium diiodide (PDAI₂) as AX₂.

### 7) Example 7

A semiconductor layer and a thin-film transistor substantially identical to those of Example 1 were fabricated in substantially the same manner as in Example 1 except that 3-amino methyl piperidinium diiodide (3AMPI₂) was used instead of propane diammonium diiodide (PDAI₂) as AX₂.

### 8) Example 8

A semiconductor layer and a thin-film transistor substantially identical to those of Example 1 were fabricated in substantially the same manner as in Example 1 except that 4-amino methyl piperidinium diiodide (4AMPI₂) was used instead of propane diammonium diiodide (PDAI₂) as AX₂.

### 9) Example 2-1

A semiconductor layer and a thin-film transistor substantially identical to those of Example 2 were fabricated in substantially the same manner as in Example 1 except that 150 mol of butane diammonium diiodide (BDAI₂) was used.

### 10) Example 2-2

A semiconductor layer and a thin-film transistor substantially identical to those of Example 2 were fabricated in substantially the same manner as in Example 1 except that 200 mol of butane diammonium diiodide (BDAI₂) was used.

### 11) Example 2-3

A semiconductor layer and a thin-film transistor substantially identical to those of Example 2-2 were fabricated in substantially the same manner as in Example 1 except that annealing was performed at a temperature of 180° C.

### 12) Comparative Example 1

A semiconductor layer and a thin-film transistor substantially identical to those of Example 1 were fabricated in substantially the same manner as in Example 1 except that phenylethylammonium iodide (PEAI) was used instead of propane diammonium diiodide (PDAI₂) as AX₂.

### 13) Comparative Example 2

A semiconductor layer and a thin-film transistor substantially identical to those of Example 2 were fabricated in substantially the same manner as in Example 1 except that 100 mol of formamidenium iodine (FAI) was added, 17 mol of butane diammonium diiodine (BDAI₂) was used and annealing was performed at a temperature of 100° C.

The fabrication conditions of Examples 1 to 8, Examples 2-1 to 2-3 and Comparative Examples 1 and 2 are shown in Table 1 below:

TABLE 1

| | Compound | Mole Ratio | Annealing |
|---|---|---|---|
| | (Carbon Number) | (AX₂:SnI₂) | Temperature (° C.) |
| Example 1 | PDASnI4(C3) | 1:1 | 150 |
| Example 2 | BDASnI4(C4) | 1:1 | 150 |
| Example 3 | PeDASnI4(C5) | 1:1 | 150 |
| Example 4 | HDASnI4(C6) | 1:1 | 150 |
| Example 5 | HepDASnI4(C7) | 1:1 | 150 |
| Example 6 | ODASnI4(C8) | 1:1 | 150 |
| Example 7 | 3AMPSnI4 | 1:1 | 150 |
| Example 8 | 4AMPSnI4 | 1:1 | 150 |
| Example 2-1 | BDASnI4(C4) | 1.5:1 | 150 |
| Example 2-2 | BDASnI4(C4) | 2:1 | 150 |
| Example 2-3 | BDASnI4(C4) | 2:1 | 180 |
| Comparative | PEA2SnI4 | 2:1 | 150 |
| Example 1 | | | |
| Comparative | BDA-FASnI4(C4) | 1:7 | 100 |
| Example 2 | | | |

### Evaluation

### 1. Crystal Structure Characteristics

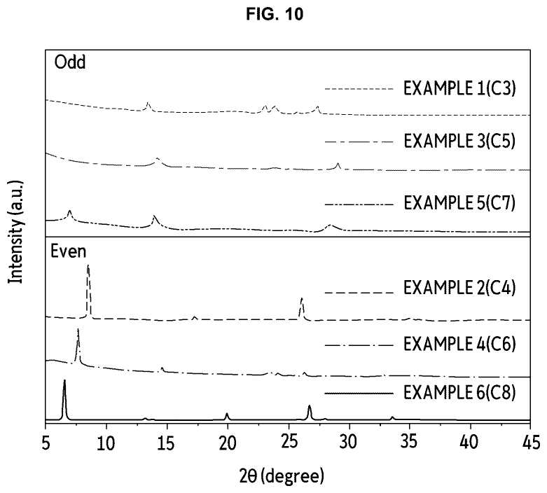

The crystal structure characteristics of the semiconductor layers of Examples 1 to 8 are shown in FIGS. 10 to 16.

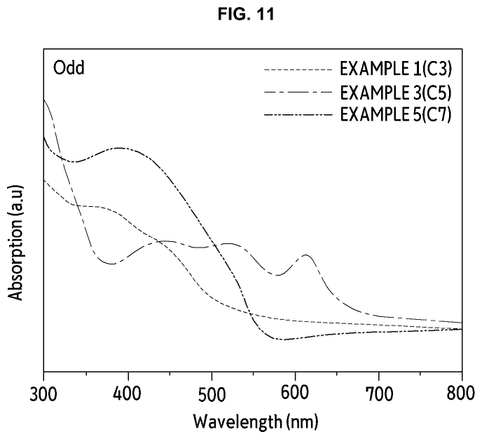

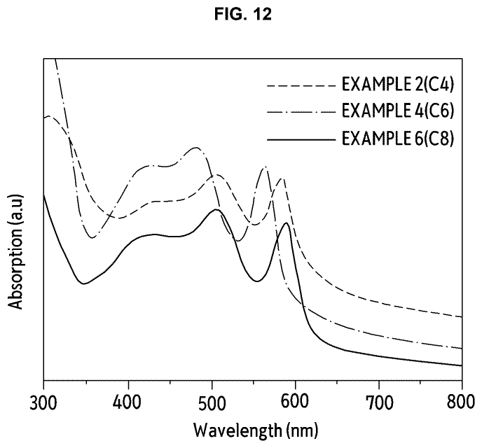

FIG. 10 is a graph showing an XRD (X-ray diffraction) of semiconductor layers of Examples 1 to 6 fabricated according to an embodiment. FIG. 11 is a graph showing UV-Vis absorption of semiconductor layers of Examples 1, 3 and 5 fabricated according to an embodiment. FIG. 12 is a graph showing UV-Vis absorption of semiconductor layers of Examples 2, 4 and 6 fabricated according to an embodiment.

According to the results shown in FIGS. 10, 11 and 12, it can be seen that when the ammonium ion of the perovskite compound is a linear alkyl group, the crystallinity is good if the number of carbon atoms is even. On the contrary, it can be seen that the crystallinity is deteriorated if the number of carbon atoms of the linear alkyl group is odd.

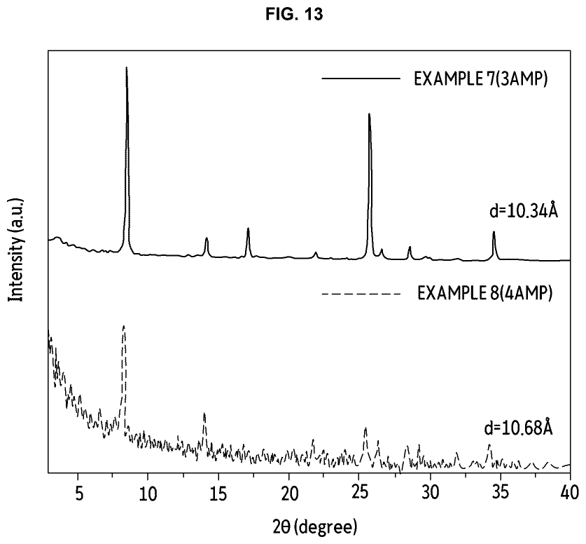

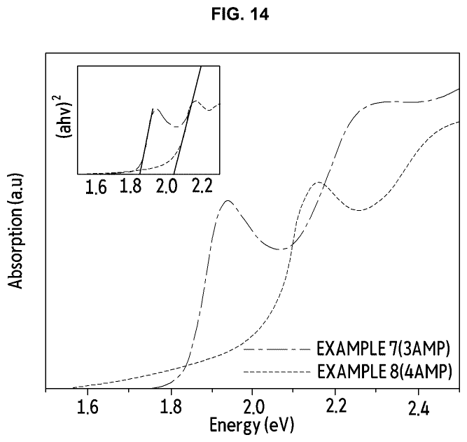

FIG. 13 is a graph showing an XRD (X-ray diffraction) of semiconductor layers of Examples 7 and 8 fabricated according to an embodiment. FIG. 14 is a graph showing UV-Vis absorption of semiconductor layers of Examples 7 and 8 fabricated according to an embodiment, in which the inset is a Tauc plot.

It can be seen from the results shown in FIGS. 13 and 14 that, when the ammonium ion of the perovskite compound is cyclic, Example 7, in which ammonium is at the carbon 3 position of the 6-ring ring structure, has better crystallinity than Example 8, in which ammonium is at the carbon 4 position of the 6-ring ring structure.

According to the results shown in FIG. 13, the distance between the octahedral layers is 10.34 Å in Example 7 and 10.68 Å in Example 8. The distance between the octahedral layers is smaller in Example 7, which may mean that the bonding strength is stronger in Example 7.

It can be seen from the inset of FIG. 14 by comparing the slopes that the band gap of Example 7 is smaller than that of Example 8.

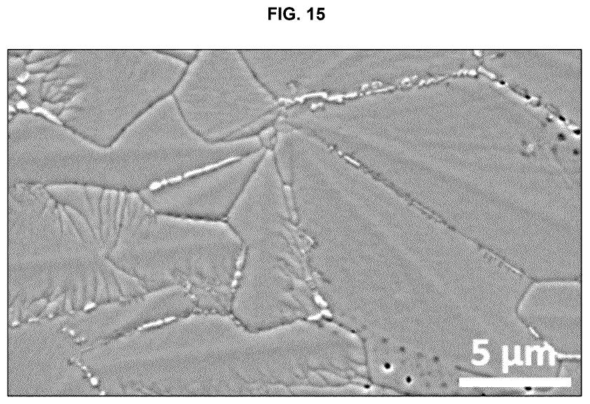

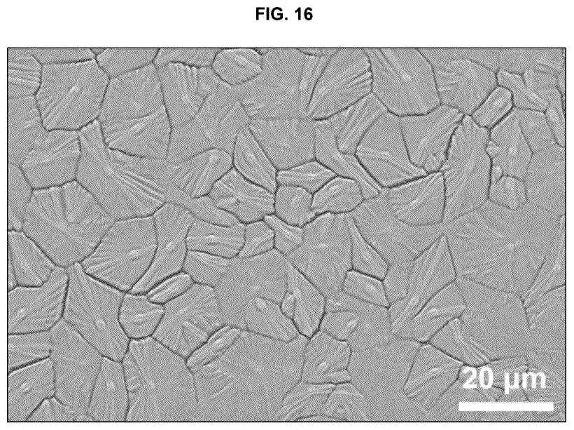

FIG. 15 is an SEM (scanning electron microscope) image of the semiconductor layer of Example 2 fabricated according to an embodiment. FIG. 16 is an SEM (scanning electron microscope) image of the semiconductor layer of Example 7 fabricated according to an embodiment.

It can be seen from the results shown in FIGS. 15 and 16 that the grain size of Examples 2 and 7 fabricated according to the embodiment is on average 10 μm or more.

### 2. Electrical Characteristics

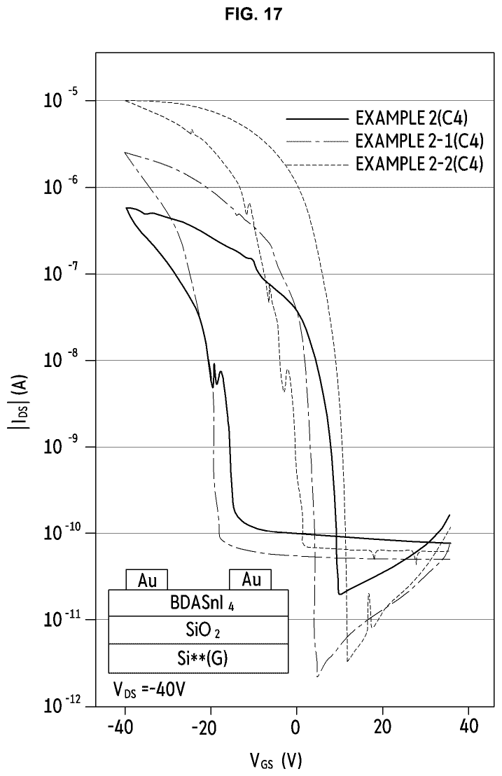

The electrical characteristics of the thin-film transistors of Examples 1 to 8, Examples 2-1 to 2-3, and Comparative Example 2 are shown in FIGS. 17 to 20.

FIG. 17 shows transition curves of Example 2, Example 2-1 and Example 2-2 fabricated according to an embodiment.

Specifically, FIG. 17 shows the transition curves according to the mole ratio of AX₂:SnI₂. The mole ratio of AX₂:SnI₂ is 1:1 in Example 2, 1.5:1 in Example 2-1, and 2:1 in Example 2-2. It can be seen from the results shown in FIG. 17 that the on-off ratio increases as the mole ratio of AX₂ increases. In particular, it can be seen that the off-currents of Example 2, Example 2-1 and Example 2-2 are similar, but the on-current increases as the mole ratio of AX₂ increases.

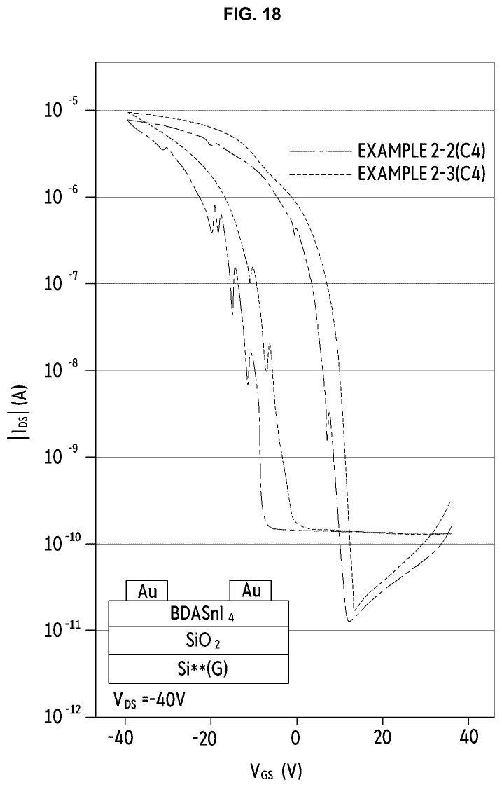

FIG. 18 shows transition curves of Example 2-2 and Example 2-3 fabricated according to an embodiment.

Specifically, FIG. 18 shows transition curves according to the annealing temperature. The annealing temperature is 150° C. in Example 2-2, and the annealing temperature is 180° C. in Example 2-3. It can be seen that the grain size increases and the current on-off ratio increases as the annealing temperature increases.

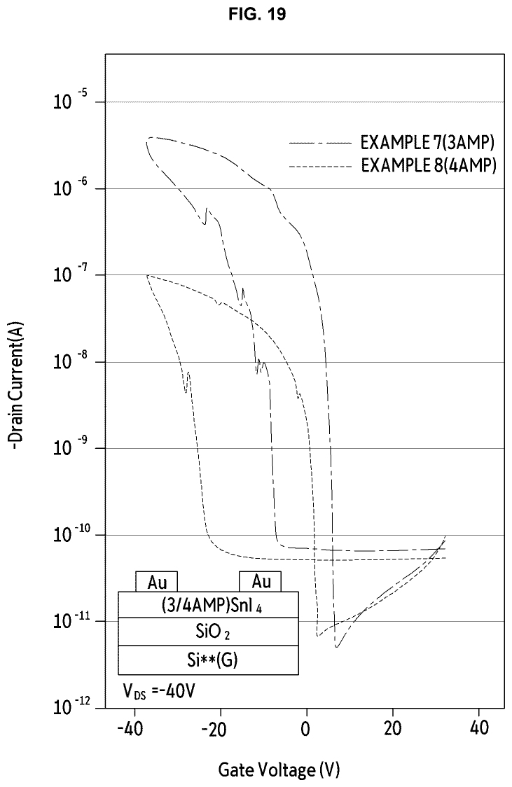

FIG. 19 shows transition curves of Examples 7 and 8 fabricated according to an embodiment.

Specifically, FIG. 19 shows transition curves according to the carbon position of the 6-ring structure when the ammonium ion of the perovskite compound is cyclic. Ammonium is at the carbon 3 position in Example 7, and ammonium is at the carbon 4 position in Example 8. According to the results shown in FIG. 19, the current on-off ratio is equal to or greater than 105 in Example 7, and the current on-off ratio is equal to or greater than 103 in Example 8. The electron mobility is 0.04 cm²/Vs in Example 7, and the electron mobility is 0.003 cm²/Vs in Example 8. It can be seen that the current on-off ratio and the electron mobility in Example 7 are greater than those of Example 8.

It can be seen from the results shown in FIGS. 13, 14 and 19 that, when the ammonium ion of the perovskite compound is cyclic, the structural stability is higher when the carbon position of the 6-ring ring structure is 3 than when the carbon position is 4.

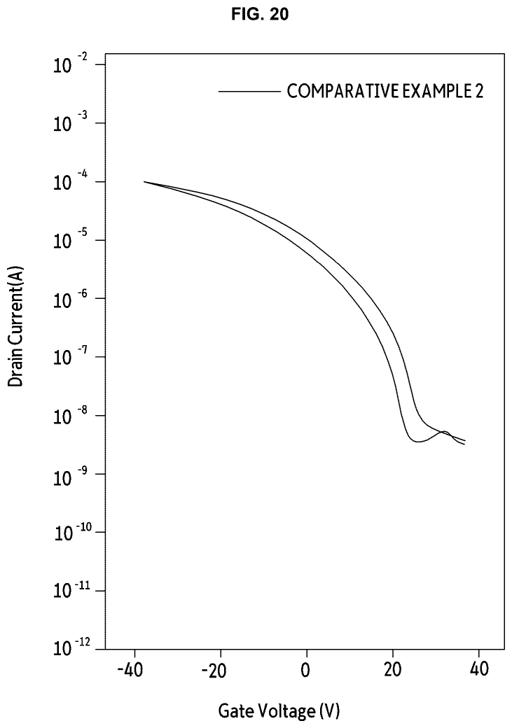

FIG. 20 shows transition curves of Comparative Example 2 fabricated according to an embodiment.

Specifically, FIG. 20 shows current curves when a monovalent cation is added to a diammonium cation. Compared to the curve of Example 2 of FIG. 17, it can be seen from FIG. 20 that the off-current increases while the on-current decreases, resulting in a decrease in the on-off ratio.

As in Example 2, when the compound includes only diammonium cations, the structural stability can be improved in a two-dimensional structure. When a monovalent cation is added to it, a two-dimensional/three-dimensional structure may be formed. While a monovalent cation (A′) allows for easy carrier transport in the three-dimensional structure, hole mobility may decrease in a two-dimensional structure. Therefore, if a monovalent cation is added to a diammonium cation, structural stability may decrease, and the electrical characteristics may also deteriorate.

### 3. Stability Check

The stability of the thin-film transistors of Examples 1 to 8, Examples 2-1 to 2-3, and Comparative Example 1 is shown in FIGS. 20 to 27.

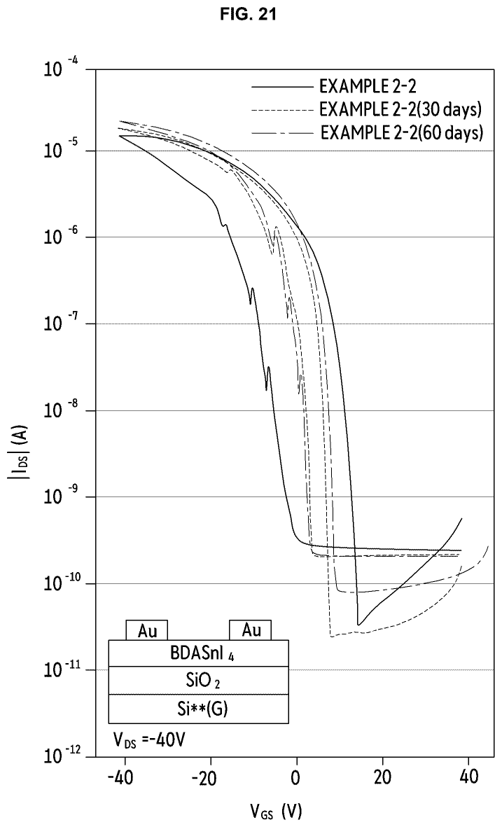

FIG. 21 shows transition curves over time of Example 2-2 fabricated according to one embodiment.

Specifically, in FIG. 21, Example 2-2 (30 days) was measured after the thin-film transistor was stored for 30 days under a nitrogen (N₂) atmosphere, and Example 2-2 (60 days) was measured after the thin-film transistor was stored for 60 days under a nitrogen (N₂) atmosphere.

It can be seen from the results shown in FIG. 21 that the current on-off ratio is maintained over time in Example 2-2. This means excellent stability. In particular, it can be seen that Example 2-2 (30 days) exhibits excellent electron mobility of approximately 0.25 cm²/Vs.

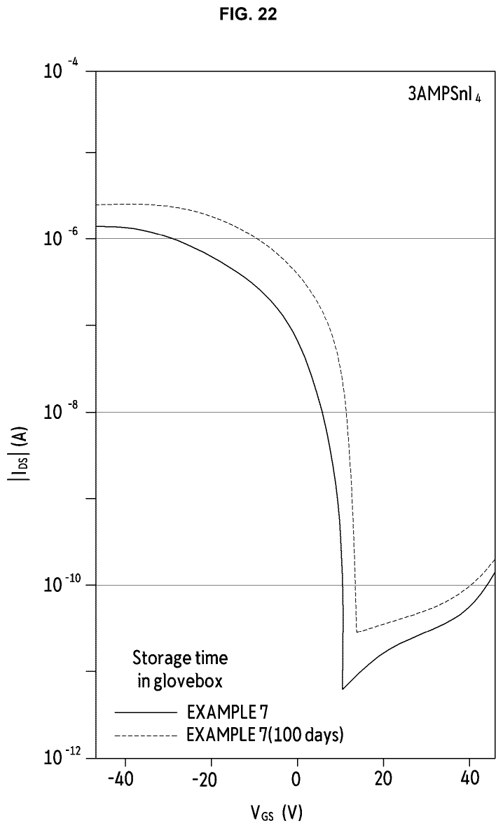

FIG. 22 shows transition curves over time of Example 7 fabricated according to an embodiment.

Specifically, Example 7 (100 days) in FIG. 22 was measured after the thin-film transistor was stored for 100 days under a nitrogen (N₂) atmosphere.

It can be seen from the results shown in FIG. 22 that the current on-off ratio is maintained over time in Example 7. This means excellent stability.

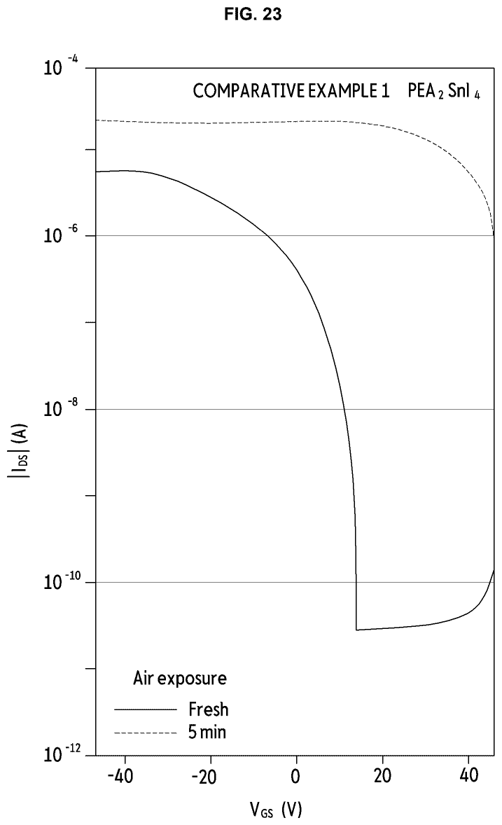

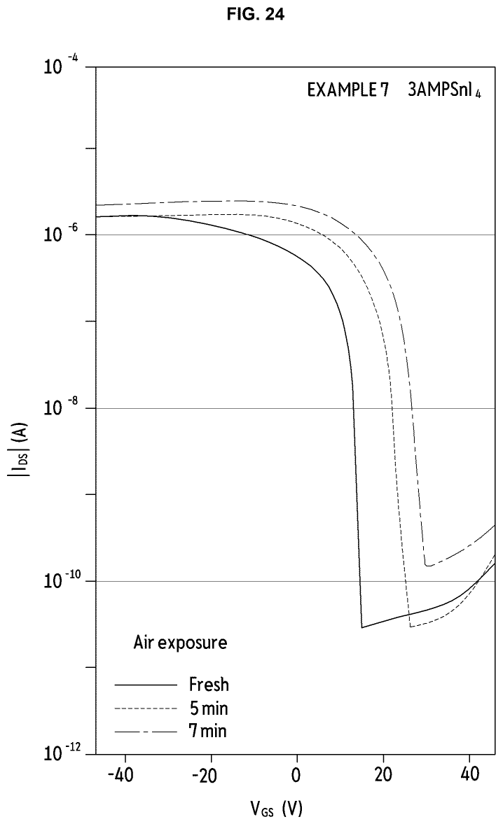

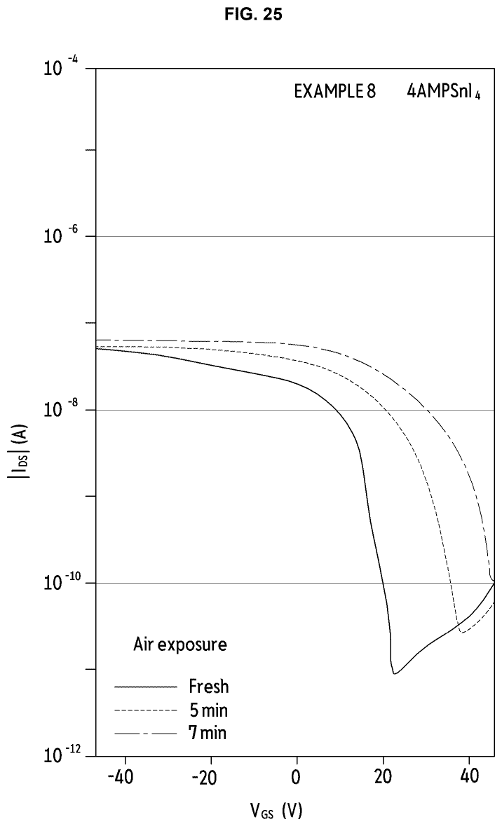

FIG. 23 shows transition curves over time when the thin-film transistor of Comparative Example 1 was exposed to air. FIG. 24 shows transition curves over time when the thin-film transistor of Example 7 was exposed to air. FIG. 25 shows transition curves over time when the thin-film transistor of Example 8 was exposed to air.

It can be seen from the results shown in FIGS. 23 to 25 that the switching characteristics of the thin-film transistor of Comparative Example 1 is lost when exposed to air. In contrast, it can be seen that the switching characteristics of the thin-film transistors of Examples 7 and 8 remain although the on-off ratio decreases. This may mean that the structural stability of the perovskite compound of diammonium cations is higher than that of the perovskite compound of single ammonium cations.

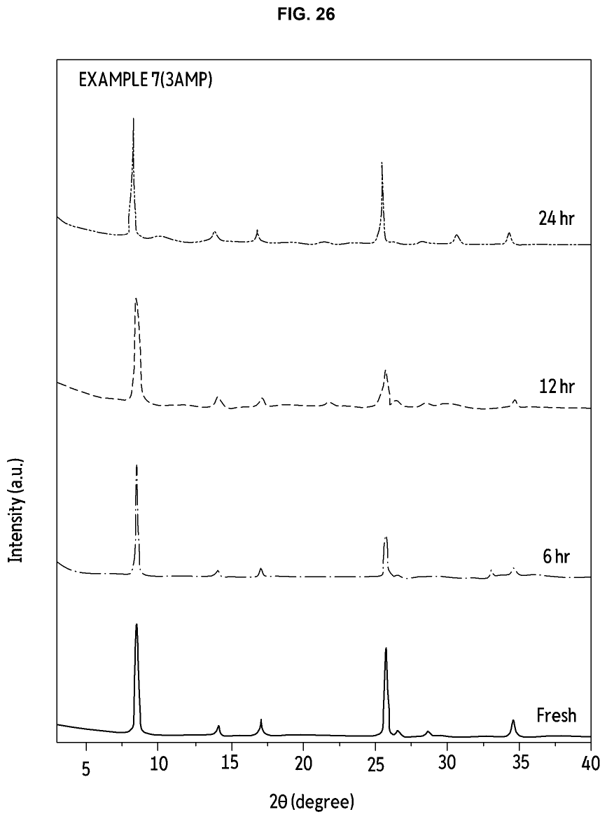

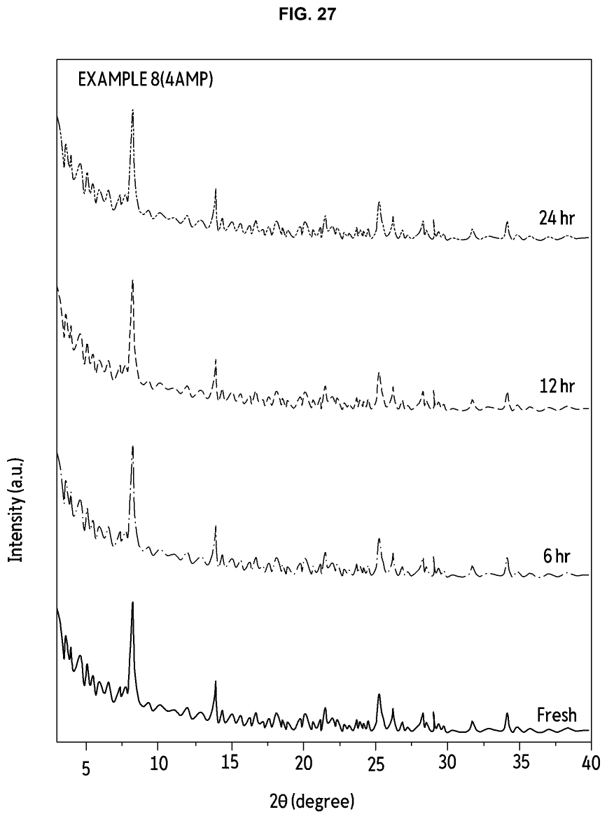

FIG. 26 is a graph showing an XRD (X-ray diffraction) over exposure time when the thin-film transistor of Example 7 is exposed to air. FIG. 27 is a graph showing an XRD (X-ray diffraction) over exposure time when the thin-film transistor of Example 8 is exposed to air.

It can be seen from the results shown in FIGS. 26 and 27 that the crystal structure of the thin-film transistors of Examples 7 and 8 is maintained even when exposed to air.

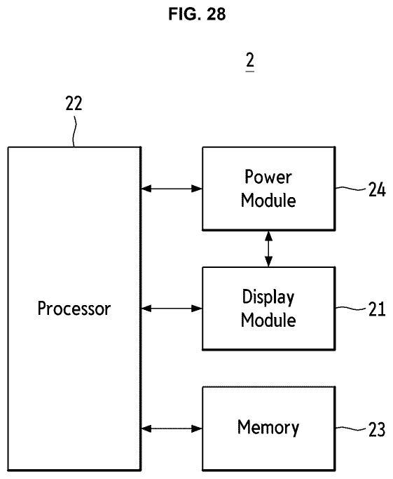

FIG. 28 is a block diagram of an electronic device according to an embodiment of the present disclosure. Referring to FIG. 28, an electronic device 2 according to an embodiment of the present disclosure may include a display module 21, a processor 22, a memory 23, and a power module 24.

The processor 22 may include at least one selected from: a central processing unit (CPU), an application processor (AP), a graphic processing unit (GPU), a communication processor (CP), an image signal processor (ISP), and a controller.

The memory 23 may store data information required for the operation of the processor 22 or the display module 21. When the processor 22 executes an application stored in the memory 23, an image data signal and/or an input control signal may be transmitted to the display module 21. The display module 21 may process the received signal and output image information through a display screen.

The power module 24 may include a power supply module such as a power adapter and a battery device, and a power conversion module that converts the power supplied by the power supply module to generate power required or desired for the operation of the electronic device 20.

At least one of the elements of the electronic device 2 described above may be included in the display device 1 according to the embodiments described above. In embodiments, some of the individual modules that function as a single module may be included in the display device 1 while some others may be provided separately from the display device 1. For example, the display device 1 may include the display module 21, and the processor 22, the memory 23 and the power module 24 may be provided as other devices inside the electronic device 2 than the display device 1.

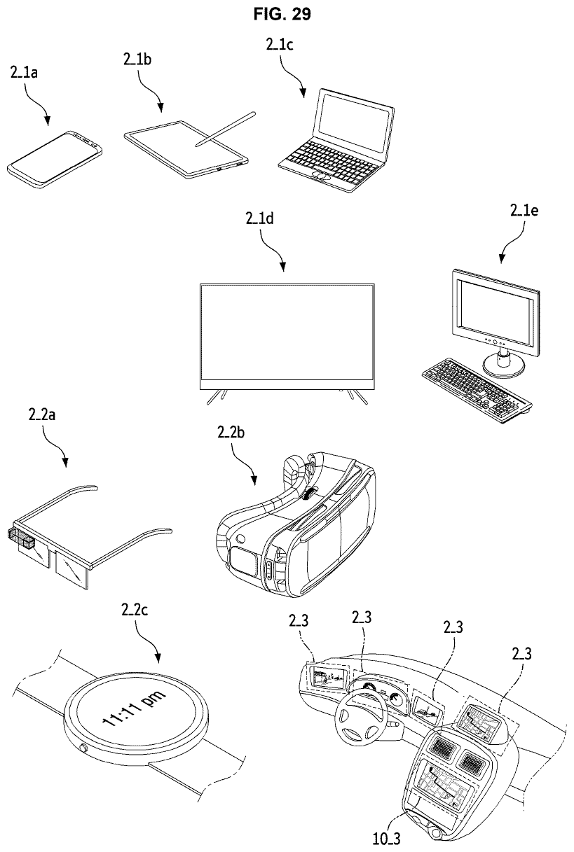

FIG. 29 is a view showing electronic devices according to a variety of embodiments of the present disclosure.

Referring to FIG. 29, a variety of electronic devices 2 the employ the display devices according to embodiments of the present disclosure may include not only electronic devices that display images such as a smart phone 2_1a, a tablet PC 2_1b, a laptop computer 2_1c, a TV 2_1d and a desktop monitor 2_1e, but also wearable electronic devices including display modules such as smart glasses 2_2a, a head-mounted display 2_2b and a smart watch 2_2c, and electronic devices for vehicles 2_3 including display modules such as a center information display (CID) placed on the dashboard, the center fascia and the dashboard of a vehicle, and a room mirror display.

Although embodiments of the present disclosure have been described with reference to the attached drawings, those skilled in the art will understand that the present disclosure can be implemented in other specific forms without changing the technical idea or essential features of the present disclosure. Therefore, it should be understood that the embodiments described above are examples in all respects and not restrictive.

What is claimed is:

1. A thin-film transistor comprising:
a substrate;
a semiconductor layer on the substrate;
a gate electrode that overlaps with a channel region of the semiconductor layer in a thickness direction of the substrate;
a gate insulator between the semiconductor layer and the gate electrode to insulate the semiconductor layer from the gate electrode; and
a source electrode and a drain electrode on a surface of the semiconductor layer,
wherein the semiconductor layer comprises a perovskite compound represented by the following chemical formula: 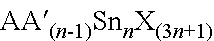
wherein A is R₁(NH₃⁺)₂ or 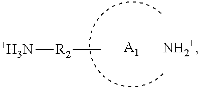
R₁ is at least one selected from the group consisting of: a substituted or unsubstituted C₁₋₂₀ linear or branched alkyl group; a substituted or unsubstituted 5-membered unsaturated or aromatic ring; a substituted or unsubstituted 6-membered unsaturated or aromatic ring; a substituted or unsubstituted 5-membered unsaturated or aromatic heterocyclic group; and a substituted or unsubstituted 6-membered unsaturated or aromatic heterocyclic group,
R₂ is a substituted or unsubstituted C₁₋₁₀ alkyl group,
A₁ comprises at least one selected from the group consisting of: a substituted or unsubstituted 5-membered unsaturated or aromatic heterocyclic group; and a substituted or unsubstituted 6-membered unsaturated or aromatic heterocyclic group,
the heterocyclic group comprises at least one selected from the group consisting of N, O and S,
A′ comprises at least one selected from the group consisting of Rb, Cs, K, Na, Mg, Ca, Sr, Ba and an organic cation, and
X comprises halogen, wherein n denotes an integer equal to or greater than one.

2. The thin-film transistor of claim 1, wherein the R₁ comprises C₁₋₂₀ alkyl group, and
wherein the A₁ comprises a substituted or unsubstituted 6-membered unsaturated or aromatic heterocyclic group.

3. The thin-film transistor of claim 2, wherein the R₁ comprises alkyl group of C₂ₘ, wherein m is an integer from 1 to 10.

4. The thin-film transistor of claim 1, wherein n is 1.

5. The thin-film transistor of claim 1, wherein the semiconductor layer comprises grains, and a size of the grains ranges from 10 μm to 50 μm.

6. The thin-film transistor of claim 1, wherein a thickness of the semiconductor layer ranges from 1 nm to 100 nm.

7. The thin-film transistor of claim 1, wherein in the perovskite compound, a content of A ranges from 50 mol % to 300 mol % based on 100 mol % of tin (Sn).

8. The thin-film transistor of claim 1, wherein an electron mobility is equal to or less than 10 cm²/Vs.

9. The thin-film transistor of claim 1, wherein a current on-off ratio ranges from 10 to 10⁷.

10. A display device comprising:
a light-emitting element and a thin-film transistor,
wherein the thin-film transistor comprises:
a substrate;
a semiconductor layer on the substrate;
a gate electrode that overlaps with a channel region of the semiconductor layer in a thickness direction of the substrate;
a gate insulator between the semiconductor layer and the gate electrode to insulate the semiconductor layer from the gate electrode; and
a source electrode and a drain electrode on a surface of the semiconductor layer,
wherein the semiconductor layer comprises a perovskite compound represented by the following chemical formula: 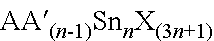
wherein A is R₁(NH₃⁺)₂ or 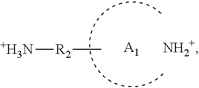
R₁ comprises at least one of: a substituted or unsubstituted C₁₋₂₀ linear or branched alkyl group; a substituted or unsubstituted 5-membered unsaturated or aromatic ring; a substituted or unsubstituted 6-membered unsaturated or aromatic ring; a substituted or unsubstituted 5-membered unsaturated or aromatic heterocyclic group; and a substituted or unsubstituted 6-membered unsaturated or aromatic heterocyclic group,
R₂ is a substituted or unsubstituted C₁₋₁₀ alkyl group,
A₁ comprises at least one of: a substituted or unsubstituted 5-membered unsaturated or aromatic heterocyclic group; and a substituted or unsubstituted 6-membered unsaturated or aromatic heterocyclic group,
the heterocyclic group comprises at least one selected from the group consisting of N, O and S, A′ comprises at least one of Rb, Cs, K, Na, Mg, Ca, Sr, Ba and an organic cation, and
X comprises halogen, wherein n denotes an integer equal to or greater than one, and
wherein one selected from the source electrode and the drain electrode is electrically connected to the light-emitting element.

11. The display device of claim 10, wherein the semiconductor layer comprises grains, and a size of the grains ranges from 10 μm to 50 μm.

12. The display device of claim 10, wherein in the perovskite compound, a content of A ranges from 50 mol % to 300 mol % based on 100 mol % of the tin (Sn).

13. A method for fabricating a thin-film transistor, the method comprising:
preparing a perovskite precursor by mixing AX₂, SnX₂ and a solvent; and
coating and heat-treating the perovskite precursor on a substrate to form a semiconductor layer,
wherein the semiconductor layer comprises a perovskite compound represented by the following chemical formula: 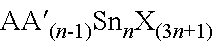
wherein A is R₁(NH₃⁺)₂ or 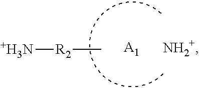
R₁ comprises at least one of: a substituted or unsubstituted C₁₋₂₀ linear or branched alkyl group; a substituted or unsubstituted 5-membered unsaturated or aromatic ring; a substituted or unsubstituted 6-membered unsaturated or aromatic ring; a substituted or unsubstituted 5-membered unsaturated or aromatic heterocyclic group; and a substituted or unsubstituted 6-membered unsaturated or aromatic heterocyclic group,
R₂ is a substituted or unsubstituted C₁₋₁₀ alkyl group,
A₁ comprises at least one selected from the group consisting of: a substituted or unsubstituted 5-membered unsaturated or aromatic heterocyclic group; and a substituted or unsubstituted 6-membered unsaturated or aromatic heterocyclic group,
the heterocyclic group comprises at least one selected from the group consisting of N, O and S, and X comprises halogen.

14. The method of claim 13, wherein a mole ratio between AX₂ and SnX₂ is 0.5:1 to 3:1.

15. The method of claim 13, wherein the heat treatment is performed at a temperature of 100° C. to 200° C.

16. The method of claim 13, wherein the perovskite precursor further comprises A′X, and wherein A′ comprises at least one selected from the group consisting of Rb, Cs, K, Na, Mg, Ca, Sr, Ba, and an organic cation.

17. The method of claim 13, further comprising: after the forming the semiconductor layer,
forming a source electrode and a drain electrode spaced apart from each other on the semiconductor layer;
forming a gate insulator on the semiconductor layer, the source electrode and the drain electrode; and
forming a gate electrode on the gate insulator,
wherein a channel region of the semiconductor layer and the gate electrode overlap each other in a thickness direction of the substrate.

18. The method of claim 13, further comprising: prior to the forming the semiconductor layer,
forming a gate electrode on the substrate;
forming a gate insulator covering the gate electrode;
forming a source electrode and a drain electrode spaced apart from each other on the gate insulator; and
forming a semiconductor layer covering the source electrode and the drain electrode,
wherein a channel region of the semiconductor layer and the gate electrode overlap each other in a thickness direction of the substrate.

19. The method of claim 13, further comprising: prior to the forming the semiconductor layer,
forming a gate electrode on the substrate;
forming a gate insulator on the gate electrode; and
after the forming the semiconductor layer,
forming a source electrode and a drain electrode on the semiconductor layer.

20. An electronic device comprising:
a display device to provide images; and
a processor to transmit an image data signal to the display device,
wherein the display device comprises:
a light-emitting element and a thin-film transistor,
wherein the thin-film transistor comprises:
a substrate;
a semiconductor layer on the substrate;
a gate electrode that overlaps with a channel region of the semiconductor layer in a thickness direction of the substrate;
a gate insulator between the semiconductor layer and the gate electrode to insulate the semiconductor layer from the gate electrode; and
a source electrode and a drain electrode on a surface of the semiconductor layer,
wherein the semiconductor layer comprises a perovskite compound represented by the following formula: 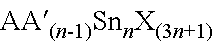
wherein A is R₁(NH₃⁺)₂ or 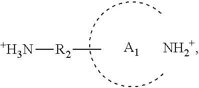
R₁ comprises at least one selected from the group consisting of: a substituted or unsubstituted C₁₋₂₀ linear or branched alkyl group; a substituted or unsubstituted 5-membered unsaturated or aromatic ring; a substituted or unsubstituted 6-membered unsaturated or aromatic ring; a substituted or unsubstituted 5-membered unsaturated or aromatic heterocyclic group; and a substituted or unsubstituted 6-membered unsaturated or aromatic heterocyclic group,
R₂ is a substituted or unsubstituted C₁₋₁₀ alkyl group,
A₁ comprises at least one selected from the group consisting of: a substituted or unsubstituted 5-membered unsaturated or aromatic heterocyclic group; and a substituted or unsubstituted 6-membered unsaturated or aromatic heterocyclic group,
the heterocyclic group comprises at least one selected from the group consisting of N, O and S,
A′ comprises at least one selected from the group consisting of Rb, Cs, K, Na, Mg, Ca, Sr, Ba and an organic cation, and X comprises halogen, wherein n denotes an integer equal to or greater than one, and
wherein one selected from the source electrode and the drain electrode is electrically connected to the light-emitting element.
